(19) United States
(12) Patent Application Publication
(10) Pub. No.: US 2026/0062832 A1
(43) Pub. Date: Mar. 5, 2026

(54) Bulk Silicon Carbide Crystal Growth System with 3D-Printed Parts

(71) Applicant: Wolfspeed, Inc., Durham, NC (US)

(72) Inventors: Brian Bennett Haidet, Raleigh, NC (US); Caleb Andrew Kent, Durham, NC (US); Alexander Kevin Shveyd, Chapel Hill, NC (US); Yuri I. Khlebnikov, Raleigh, NC (US); Valeri Fedorovich Tsvetkov, Durham, NC (US); Elif Balkas, Cary, NC (US)

(21) Appl. No.: 18/963,082

(22) Filed: Nov. 27, 2024

Related U.S. Application Data
(60) Provisional application No. 63/689,298, filed on Aug. 30, 2024.

(51) Int. Cl. C30B 23/02; B33Y 70/10; B33Y 80/00; C30B 29/36

(52) U.S. Cl. CPC C30B 23/02; B33Y 70/10; B33Y 80/00; C30B 29/36

(57) ABSTRACT

A silicon carbide crystal growth sublimation system is provided. The system comprises a crucible, a seed holder, an insulation material at least partially surrounding the crucible, and a source material comprising silicon carbide contained within the crucible. At least a portion of the source material, crucible, seed holder, or insulation material is 3D printed from a 3D printing composition comprising a ceramic material and a binder.

### PRIORITY CLAIM

The present application claims the benefit of priority of U.S. Provisional Application Ser. No. 63/689,298, filed on Aug. 30, 2024, which is incorporated herein by reference for all purposes.

### FIELD

The present disclosure relates generally to semiconductor workpieces and semiconductor workpiece fabrication.

### BACKGROUND

Power semiconductor devices are used to carry large currents and support high voltages. A wide variety of power semiconductor devices are known in the art including, for example, transistors, diodes, thyristors, power modules, discrete power semiconductor packages, and other devices. For instance, example semiconductor devices may be transistor devices such as Metal Oxide Semiconductor Field Effect Transistors (“MOSFET”), bipolar junction transistors (“BJTs”), Insulated Gate Bipolar Transistors (“IGBT”), Gate Turn-Off Transistors (“GTO”), junction field effect transistors (“JFET”), high electron mobility transistors (“HEMT”) and other devices. Example semiconductor devices may be diodes, such as Schottky diodes or other devices.

Power semiconductor devices may be packaged into various semiconductor device packages, such as discrete semiconductor device packages and power modules. Power modules may include one or more power devices and other circuit components and can be used, for instance, to dynamically switch large amounts of power through various components, such as motors, inverters, generators, and the like.

Semiconductor devices may be fabricated from wide bandgap semiconductor materials, such as silicon carbide and/or Group III nitride-based semiconductor materials. The fabrication process for power semiconductor devices may require processing of wide bandgap semiconductor wafers, such as silicon carbide semiconductor wafers.

Single crystal silicon carbide (SiC) has proven to be a very useful wafer material in the manufacture of such semiconductor devices. Due to its physical strength and excellent resistance to many chemicals, SiC may be used to fabricate very robust substrates adapted for use in the semiconductor industry. SiC has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

SiC crystalline material may be produced using various seeded sublimation growth processes. In a typical SiC growth process, a seed material and source material are arranged in a reaction crucible which is then heated to the sublimation temperature of the source material. By controlled heating of the environment surrounding the reaction crucible, a thermal gradient is developed between the sublimating source material and the marginally cooler seed material. By means of the thermal gradient, source material in a vapor phase is transported onto the seed material where it condenses to grow a bulk crystalline boule. This type of crystalline growth process is commonly referred to as physical vapor transport (PVT) process.

A resulting SiC boule may then be sliced using conventional techniques into wafers, and the individual wafers may then be used as seed material for a seeded sublimation growth process, or as substrates upon which a variety of semiconductor devices (e.g., power semiconductor devices and optical applications, such as LEDs, windows, photo-diodes, etc.) may be formed.

### SUMMARY

Aspects and advantages of embodiments of the present disclosure will be set forth in part in the following description, or can be learned from the description, or can be learned through practice of the embodiments.

In one aspect, the present disclosure provides an example silicon carbide crystal growth sublimation system including a crucible and a 3D printed source material within the crucible. The source material includes silicon carbide powder and a binder.

In another aspect, the present disclosure provides an example silicon carbide crystal growth sublimation system. The system includes a crucible, a seed holder, an insulation material at least partially surrounding the crucible, and a source material including silicon carbide contained within the crucible. At least a portion of the crucible, seed holder, or insulation material is 3D printed from a 3D printing composition including a ceramic material and a binder.

In another aspect, the present disclosure provides an example method of growing a single-crystal of silicon carbide (SiC crystal) using a physical vapor transport (PVT) process in a sublimation system. The method includes placing a source material containing silicon carbide in a reaction crucible and heating the sublimation system to a temperature of at least 2000° C. At least one component of the sublimation system includes a 3D printed part made from a 3D printing composition including a ceramic material and a binder.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a sublimation system according to example embodiments of the present disclosure;

FIG. 2 depicts a sublimation system according to example embodiments of the present disclosure;

FIG. 3 depicts a sublimation system according to example embodiments of the present disclosure;

FIG. 4 depicts a powder bed fusion system that may be used according to example embodiments of the present disclosure;

FIG. 5 depicts a fused deposition modeling system according to example embodiments of the present disclosure;

FIG. 6 depicts a three-dimensional structure that may be formed from the composition according to example embodiments of the present disclosure;

FIGS. 7A-7C are cross-sectional views of FIG. 6 taken along a line 3A-3A, depicting a process for forming a three-dimensional structure according to example embodiments of the present disclosure;

FIG. 8 depicts an example complex structure that may be 3D printed according to example embodiments of the present disclosure;

FIG. 9 depicts an example complex structure that may be 3D printed according to example embodiments of the present disclosure;

FIG. 10 depicts an example complex structure that may be 3D printed according to example embodiments of the present disclosure;

FIG. 11 depicts a cross section of an example complex structure that may be 3D printed according to example embodiments of the present disclosure;

FIG. 12 depicts a cross section of an example complex structure that may be 3D printed according to example embodiments of the present disclosure;

FIGS. 13A-13B depict cross sections of example complex structures that may be 3D printed according to example embodiments of the present disclosure;

FIG. 14 depicts an example complex structure that may be 3D printed according to example embodiments of the present disclosure;

FIG. 15 depicts a cross section of an example complex structure that may be 3D printed according to example embodiments of the present disclosure;

FIG. 16 depicts a cross section of an example complex structure that may be 3D printed according to example embodiments of the present disclosure;

FIG. 17 depicts a flow chart diagram of an example method according to example embodiments of the present disclosure;

FIG. 18A depicts a cross section of an example complex structure that may be 3D printed according to example embodiments of the present disclosure;

FIG. 18B depicts a cross section of an example complex structure that may be 3D printed according to example embodiments of the present disclosure;

FIG. 18C depicts a top view of the complex structure shown in FIG. 18A;

FIG. 19A depicts a cross section of an example complex structure that may be 3D printed according to example embodiments of the present disclosure;

FIG. 19B depicts a cross section of an example complex structure that may be 3D printed according to example embodiments of the present disclosure;

FIG. 20 depicts a cross section of an example complex structure that may be 3D printed according to example embodiments of the present disclosure;

FIG. 21 depicts a cross section of an example complex structure that may be 3D printed according to example embodiments of the present disclosure;

FIG. 22A depicts a source retention mechanism according to example embodiments of the present disclosure; and

FIG. 22B depicts a source retention mechanism according to example embodiments of the present disclosure.

FIGS. 23A-30 depict example crystal growth systems that include a baffle according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to systems for growing crystalline silicon carbide (SiC), such as single crystal SiC. In some SiC growth processes, the reaction crucible is made of carbon (including, for example graphite and/or other carbon materials) and is heated using an inductive or resistive heating technique. The heating coils and associated insulation are carefully positioned in relation to the reaction crucible to establish and maintain the desired thermal gradient. Source material, such as powdered SiC, is commonly used in conjunction with vertically oriented reaction crucibles. The powdered SiC is retained in a lower portion of the reaction crucible and the seed material is positioned in an upper portion of the reaction crucible during the PVT process.

The various components of SiC crystal growth systems may be formed by molding (e.g., extrusion, isostatic pressing, compression molding, or vibration molding) a paste including powdered graphite precursors such as coke or carbon black and a binder such as coal tar pitch or petroleum pitch. The molded parts are then typically baked, densified by impregnation with a further graphite precursor, and then graphitized at extremely high temperatures.

Aspects of the present disclosure are directed to forming the SiC grower components and/or the SiC source material, by 3D printing. Advantages of using 3D printing techniques to produce such components include the ability to incorporate more complex part geometries, to use cheaper raw materials in some cases (e.g., porous graphite), and to allow for rapid design iteration. While grower components may be expensive or difficult to manufacture, 3D printing can simplify the production into a single fabrication process. As such, production can be fast and may not require post-processing steps that otherwise may be required.

When the source material is 3D printed, very complex geometries can be constructed for almost no additional fabrication time, allowing for better control of thermal gradients, surface area, and flow paths within the source material. For example, a 3D printed part may include more complex geometry, including more complex shapes, features, symmetry, asymmetry, dimensions, thicknesses, and/or appendages to improve control. As such, significant performance improvements can be achieved compared to using a conventional powder bed source material.

Additionally, from an automation and factory efficiency perspective, having pre-made parts printed from high-purity SiC simplifies the crucible-build procedure. If the source material can be prepared via a separate modular process, the act of assembling a crucible can be simplified.

In other components (e.g., carrier rings for the seed material), purity, mechanical and chemical stability, and cost can be improved through the use of 3D printing compared to other production techniques.

While 3D printing techniques are suitable for fabricating parts useful at relatively mild temperatures, the resulting parts would not be able to withstand the silicon-rich, extreme temperature environments of a SiC sublimation system. However, through the techniques described herein, the reactor and crucible components can be printed at relatively low temperatures but designed to convert to stable solids at extremely high temperatures (e.g., 2000° C.). For example, through selective control of the components of a 3D printing composition including a binder and a ceramic material, a 3D printed part formed from the composition can survive the harsh environment within a SiC crystal growth crucible.

In the case of a 3D printed SiC source material, the SiC will evaporate, but the remaining material, which is mostly pure carbon resulting from degradation of the binder, remains structurally sound. At the temperatures needed for SiC sublimation (e.g., above 2000° C.), any polymers used for the binder will either become graphite or vitreous carbon.

Advantageously, some binders can degrade to a carbon scaffold having a suitable amount of long-term strength. The carbon grain growth of the converting binder influences the strength of the resulting carbon scaffold and can be controlled through selection of the type of binder and the heat/vacuum treatment used. For cases where ceramic particles are used as an aggregate, this remaining carbon scaffold can either separately envelop each SiC particle, or bond directly to the SiC particle surface.

Accordingly, example aspects of the present disclosure are directed to a SiC crystal growth sublimation system comprising a crucible and a 3D printed source material comprising SiC powder and a binder. Other example aspects of the present disclosure are directed to a SiC crystal growth sublimation system comprising a crucible, a seed holder, an insulation material at least partially surrounding the crucible, and a source material comprising silicon carbide. At least a portion of the crucible, seed holder, or insulation material is 3D printed and comprises a ceramic material and a binder.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

The terminology used herein is for the purpose of describing particular embodiments only and is not intended to be limiting of the disclosure. As used herein, the singular forms “a,” “an” and “the” are intended to include the plural forms as well, unless the context clearly indicates otherwise. It will be further understood that the terms “comprises” “comprising,” “includes” and/or “including” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

It will be understood that when an element such as a layer, structure, region, or substrate is referred to as being “on” or extending “onto” another element, it may be directly on or extend directly onto the other element or intervening elements may also be present and may be only partially on the other element. In contrast, when an element is referred to as being “directly on” or extending “directly onto” another element, there are no intervening elements present, and may be partially directly on the other element. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

As used herein, a first structure “at least partially overlaps” or is “overlapping” a second structure if an axis that is perpendicular to a major surface of the first structure passes through both the first structure and the second structure. A “peripheral portion” of a structure includes regions of a structure that are closer to a perimeter of a surface of the structure relative to a geometric center of the surface of the structure. A “center portion” of the structure includes regions of the structure that are closer to a geometric center of the surface of the structure relative to a perimeter of the surface. “Generally perpendicular” means within 15 degrees of perpendicular. “Generally parallel”means within 15 degrees of parallel.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures.

Embodiments of the disclosure are described herein with reference to cross-section illustrations that are schematic illustrations of idealized embodiments (and intermediate structures) of the disclosure. The thickness of layers and regions in the drawings may be exaggerated for clarity. Additionally, variations from the shapes of the illustrations as a result, for example, of manufacturing techniques and/or tolerances, are to be expected. Thus, embodiments of the disclosure should not be construed as limited to the particular shapes of regions illustrated herein but are to include deviations in shapes that result, for example, from manufacturing. Similarly, it will be understood that variations in the dimensions are to be expected based on standard deviations in manufacturing procedures. As used herein, “approximately” or “about” includes values within 10% of the nominal value.

Like numbers refer to like elements throughout. Thus, the same or similar numbers may be described with reference to other drawings even if they are neither mentioned nor described in the corresponding drawing. Also, elements that are not denoted by reference numbers may be described with reference to other drawings.

Some embodiments of the disclosure are described with reference to semiconductor layers and/or regions which are characterized as having a conductivity type such as n type or p type, which refers to the majority carrier concentration in the layer and/or region. Thus, n type material has a majority equilibrium concentration of negatively charged electrons, while p type material has a majority equilibrium concentration of positively charged holes. Some material may be designated with a “+” or “−” (as in n+, n−, p+, p−, n++, n−−, p++, p−−, or the like), to indicate a relatively larger (“+”) or smaller (“−”) concentration of majority carriers compared to another layer or region. However, such notation does not imply the existence of a particular concentration of majority or minority carriers in a layer or region.

In the drawings and specification, there have been disclosed typical embodiments and, although specific terms are employed, they are used in a generic and descriptive sense only and not for purposes of limitation of the scope set forth in the following claims.

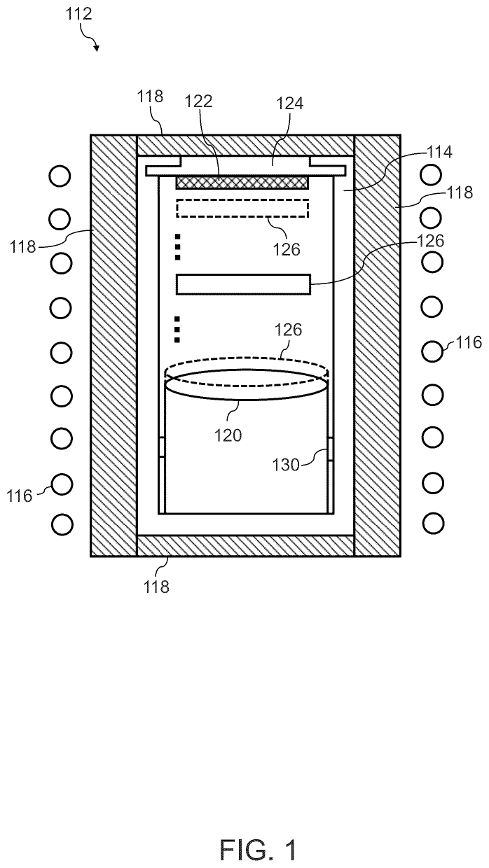

FIG. 1 is a cross sectional schematic diagram of a sublimation system 112 adapted for use in a seeded sublimation growth process of the type contemplated by certain embodiments of the disclosure. Sublimation system 112 includes a reaction crucible (also referred to as a susceptor or growth cell) 114 and a plurality of induction coils 116 adapted to heat reaction crucible 114 when electrical current is applied. Alternatively, a resistive heating approach may be applied to the heating of reaction crucible 114. Using any competent heating mechanism and approach, the temperature within a furnace housing sublimation system 112 may be controllable. The reaction crucible 114 can be made of graphite or can be 3D printed as described below.

The furnace housing sublimation system 112 may also include one or more gas inlet and gas outlet ports and associated equipment allowing the controlled introduction and evacuation of gas from an environment surrounding reaction crucible 114. The introduction and evacuation of various gases to/from the environment surrounding reaction crucible 114 may be accomplished using a variety of inlets/outlets, pipes, valves, pumps, gas sources, and controllers. It will be further understood by those skilled in the art that sublimation system 102 may further incorporate in certain embodiments a water-cooled quartz vessel.

Reaction crucible 114 may be surrounded by insulation material 118. The composition, size, and placement of insulation material 118 will vary with individual sublimation systems 112 in order to define and/or maintain desired thermal gradients (both axially and radially) in relation to reaction crucible 114. For purposes of clarity, the term, “thermal gradient,” will be used herein to describe one or more thermal gradient(s) associated with reaction crucible 114. Those skilled in the art recognize that “the thermal gradient” established in embodiments of the disclosure will contain (or may be further characterized as having) axial and radial gradients, or may be characterized by a plurality of isotherms.

Prior to establishment of the thermal gradient, reaction crucible 114 is loaded with one or more source materials. As such, the reaction crucible includes one or more portions, as least one of which is capable of holding source material 120, which is represented by a generic cylinder for simplicity but, as further described herein, can be a powdered SiC and/or a 3D printed material containing SiC particles. As illustrated in FIG. 1, source material 120 may be held in a lower portion of reaction crucible 114, as is common for one type of reaction crucible 114. Example silicon carbide source materials are disclosed in U.S. Provisional Application Ser. No. 63/689,294, filed on Aug. 30, 2024 and in U.S. Provisional Application Ser. No. 63/689,291, filed on Aug. 30, 2024, both of which are incorporated herein by reference.

A seed material 122 may be placed above or in an upper portion of reaction crucible 114. Seed material 122 may take the form of a mono-crystalline SiC seed wafer having a diameter from about 50 to about 300 mm. A SiC single crystal boule 126 will be grown from seed material 122 during the seeded sublimation growth process. The seed material 122 may have a 4H crystal structure, 6H crystal structure, or other crystal structure. The seed material 122 can be on-axis (e.g., end face parallel to the (0001) plane) or off-axis (e.g., end face non-parallel to the (0001) plane). Growth may occur on the silicon face or the carbon face of the seed material 122.

In some embodiments, the system may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 1, the baffle 126 may be located on the source material, may be spaced apart from the source material 120 and/or the seed material 126, or may be proximate the seed material 122. In some embodiments, the system 112 may include any number of baffles 126 without deviating from the scope of the present disclosure.

In the embodiment illustrated in FIG. 1, a seed holder 124 is used to hold seed material 122. Seed holder 124 is securely attached to reaction crucible 114 in an appropriate fashion using conventional techniques. For example, in the orientation illustrated in FIG. 1, seed holder 124 is attached to an uppermost portion of reaction crucible 114 to hold seed material 122 in a desired position. In one embodiment, seed holder 124 is fabricated from carbon. In another embodiment, see holder 124 is 3D printed from a composition as described below. The attachment of the seed material (i.e., a seed wafer) to a corresponding seed holder within a sublimation system may be made with, for instance, a uniform thermal contact. Various techniques may be used to implement a uniform thermal contact. For example, the seed material may be placed in direct physical contact with the seed holder, or an adhesive may be used to fix the seed material to the seed holder, so as to ensure that conductive and/or radiative heat transfer is uniform over substantially the entire area between the seed and the seed holder. Alternately, a wafer holder comprising a controlled gap structure may be used to define and maintain a desired separation gap between the seed material and the seed holder. It will also be understood by those skilled in the art that the use of a controlled gap structure requires a protective backside surface coating on the seed material (i.e., on the surface opposite to the growth surface) so that the seed material will not inadvertently sublimate during the growth process. In various embodiments, a controlled gap structure may be used to form a separation distance between the seed material and seed holder of 10 μm or less, 5 μm or less, 2 μm or less, and where practically possible less than 1 pm. The thickness of the seed material 122 may be from about 0.1 mm to about 5 mm, such as from about 0.2 m to about 2 mm, such as from about 0.3 mm to about 1 mm, such as from about 0.4 mm to about 0.7 mm.

In some embodiments, the sublimation system may include a second source material. The second source material can be a solid shaped source material according to any of the embodiments described herein or may be another type of silicon carbide vapor source material. The second source material may be located anywhere within the crucible. For example, it may be spaced axially, radially, or concentrically from a first solid source structure.

Further, the sublimation system 112 may optionally include a source material holder 130. The source material holder 130 may be, for example, one or more graphite components within the crucible that brace or support the shaped solid source material. In some embodiments, the source material holder 130 may be attached to the inner walls of the reaction crucible 114, as shown in FIG. 1.

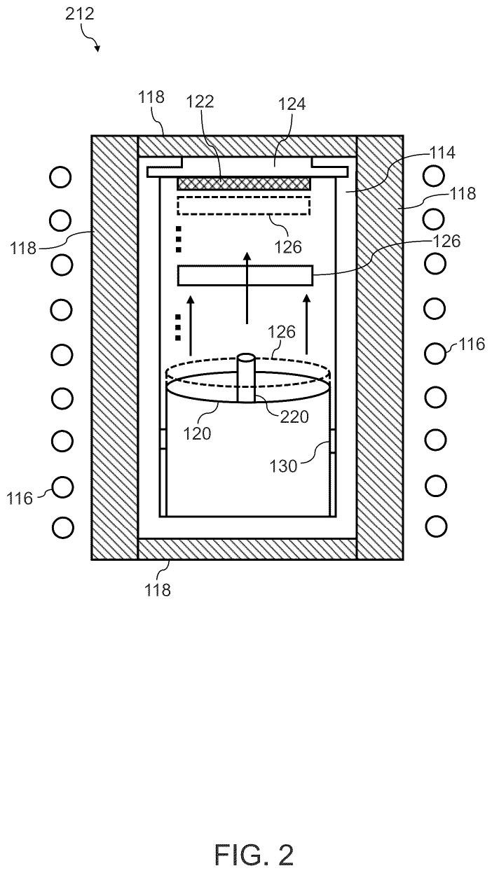

In one example embodiment, shown in FIG. 2, sublimation system 212 may be similar to that shown in FIG. 1, but also includes an inlet 220 for introducing a dopant (e.g., N₂) to the reaction crucible 114. The inlet 220, may be, for example, a tube, pipe, vent, or the like. In some embodiments, the source material 120 may surround the inlet 220. For example, in some embodiments, the solid shaped source material structure may include a channel through which the inlet 220 is provided. In other embodiments, the solid shaped source material structure may include a plurality of subcomponents (attached or detached) which surround the inlet 220. The inlet 220 may be connected to a dopant-containing gas source (not shown) and configured to introduce the dopant-containing gas to the reaction crucible 114. An example of a dopant-containing gas is nitrogen.

In some embodiments, the system 212 may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 2, the baffle 126 may be located on the source material, may be spaced apart from the source material 120 and/or the seed material 126, or may be proximate the seed material 122. In some embodiments, the system 212 may include any number of baffles 126 without deviating from the scope of the present disclosure.

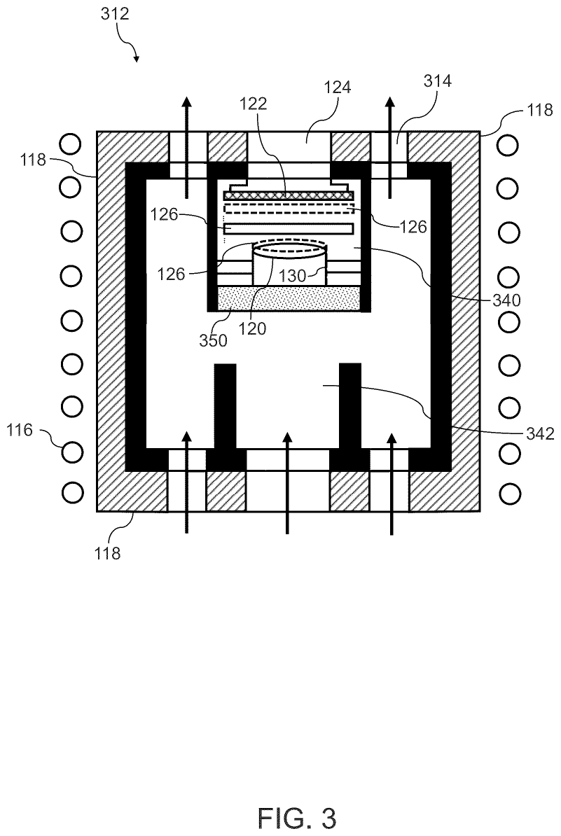

In another example embodiment, shown in FIG. 3, sublimation system 312 may be a continuous feed PVT (CF-PVT) system. In the CF-PVT system, the reaction crucible 314 may include an upper chamber 340 and a lower chamber 342. The upper chamber 340 may include the solid source material 120 and the seed material 122. The upper chamber 340 may be separated from the lower chamber 342 by a foamed structure 350. The foamed structure 350 may be formed, for example, from a gas-permeable graphite foam. The solid source material 120 may be placed on the foamed structure 350 within the upper chamber. A gaseous silicon source (e.g., trimethylsilane diluted in argon) may be supplied to the lower chamber. As the gaseous silicon source flows through the foamed structure 350, it may react with a carbon source within the foamed structure 350 (e.g., graphite) to form silicon carbide. The CF-PVT system combines the PVT process for the growth of single crystals and HTCVD process for the in-situ formation and continuous feeding of high purity polycrystalline source. The CF-PVT system may be particularly useful for growing 3C silicon carbide. In some embodiments, rather than structure 350 being a foamed structure, it may be a solid disk with holes, slots, etc.

In some embodiments, the system 212 may include a baffle 126. The baffle 126 may provide a mechanism for the transport of source vapor during sublimation of the source material 120. The baffle 126 may have any spatial orientation relative to the source material 120, the seed crystal 122, and/or the reaction crucible 114. The baffle 126 may filter or otherwise reduce impurities from the source material in a crystal growth process. The baffle 126 may provide for control of radiative heat transfer. The baffle 126 may include any of the baffles disclosed in U.S. patent application Ser. No. 18/962,454 filed on Nov. 27, 2024, which is incorporated herein by reference.

As shown in FIG. 3, the baffle 126 may be located on the source material, may be spaced apart from the source material 120 and/or the seed material 126, or may be proximate the seed material 122. In some embodiments, the system 312 may include any number of baffles 126 without deviating from the scope of the present disclosure.

In any of the embodiments shown in FIGS. 1-3 or any other suitable sublimation growth systems, reaction crucible 114 may be implemented in a number of different shapes and may hold one or more source materials accordingly. Thus, while embodiments of the present disclosure may be illustrated with certain reaction crucible designs, the scope of the present disclosure is not limited to such designs but will find application in different sublimation systems using many different types of reaction crucibles.

As mentioned above, in some embodiments, the source material 120 is 3D printed from a 3D printing composition including SiC powder and a binder. The SiC powder preferably has a median particle size (d50, as determined according to ISO 13320), sometimes referred to as grain size when formed into a solid, of about 5 μm or greater, such as about 10 μm or greater, such as about 15 μm or greater, such as about 20 μm or greater, such as about 30 μm or greater, such as about 50 μm or greater, such as about 70 μm or greater. In some embodiments, the grain size may be about 5 mm or less, such as about 1 mm or less, such as about 200 μm or less, such as about 100 μm or less, such as about 80 μm or less, such as about 60 μm or less, such as about 50 μm or less, such as about 40 μm or less, such as about 30 μm or less, such as about 20 μm or less. The particle size distribution may be relatively narrow such that at least 90% by volume of the microparticles have a size within the ranges noted above. Further, the particles may also be generally spherical to help improve processability. Such particles may, for example, have an aspect ratio (ratio of length to diameter) of from about 0.7 to about 1.3, in some embodiments from about 0.8 to about 1.2, and in some embodiments, from about 0.9 to about 1.1 (e.g., about 1).

In some examples, the SiC powder has a high purity. For example, one or more high quality source materials may be employed as SiC source material in a sublimation or evaporation system consistent with certain embodiments of the disclosure where such source material(s) contain a total concentration of less than 5 parts per million by weight (ppmwt) of metallic impurities, and less than 2 ppmwt of metallic impurities. In this context, metallic impurities include at least metals such as Ti, V, Cr, Mn, Fe, Co, Ni, Cu, Zn, Zr, Mo, Pd, Ta, and/or W. Indeed, certain embodiments may provide that the SiC source material(s) being used contain a total concentration of less than 1 ppmwt of Ti, V, Cr, Mn, Fe, Co, Ni, Cu, Zn, Zr, Mo, Pd, Ta, and/or W.

According to examples of the present disclosure, the binder may form a non-graphitizable carbon under extreme heat, for example, at pyrolysis temperatures in a range of about 1600° C. to 3000° C. Additionally, the binder may have a relatively high char yield. For example, the binder preferably has a char yield of at least about 40%, such as about 50% or more, such as about 60% or more, such as about 70% or more, such as about 80% or more, such as about 90% or more at pyrolysis temperatures in a range of about 1600° C. to about 3000° C.

Examples of suitable binders include UV curable polymer adhesives.

In some examples, the UV curable polymer adhesives may comprise one or more photosensitive monomers or oligomers capable of being polymerized by UV light. In some examples, the UV curable polymer adhesive can be a commercial photopolymer or a photopolymer formulated by mixing monomers, oligomers, photoinitiators, and other additives such as photo-absorbers, dyes, and inhibitors. The monomer/oligomer can be (but is not restricted to) an acrylate-based monomer, an acrylamide-based monomer, a polyether, an acryloyl morpholine, a polyethylene glycol, an epoxy-based monomer, or a combination of these and other monomers.

Examples of acrylate-based monomers are acrylates (e.g., behenyl acrylate, or 2-hydroxyethyl acrylate), diacrylates (e.g., polyethylene glycol diacrylate), triacrylates (e.g., trimethylolpropane triacrylate), tetraacrylates (e.g., di(trimethylolpropane) tetraacrylate), and methacrylates (e.g., (hydroxyethyl)methacrylate).

An example of a polyether is polypropylene glycol.

Examples of acrylamide-based monomer are acrylamide, and N,N′-methylenebisacrylamide.

An example of an epoxy-based monomer is epoxy cyclohexane carboxylate.

In some embodiments, the UV-curable resin may comprise one or more photosensitive acrylate or methacrylate monomers or oligomers.

The photoinitiator can be (but is not restricted to) peroxides (e.g. benzoyl peroxide), nitrogen dioxide, camphorquinone, molecular oxygen, azobisisobutyronitrile, lithium phenyl-2,4,6-trimethylbenzoylphosphinate, benzoin methyl ether, 2,2-dimethoxy-2-phenylacetophenone, 2-hydroxy-2-methylphenylpropane-1-one, a-hydroxy-acetophenone, bis(2,6-dimethoxybenzoyl)-2,4,4-trimethylpentylphosphine oxide, 2-hydroxy-2-methyl-1-phenyl-propan-1-one, 2,4,6-trimethylbenzoyldiphenylphosphine oxide, or a combination of these and other photoinitiators.

Suitable photoinitiators may be selected from the group consisting of 2,2-dimethoxy-2-phenylacetophenone, 2-hydroxy-2-methylpropiophenone, camphorquinone, bis(2,4,6-trimethylbenzoyl)-phenylphosphineoxide, benzophenone, benzoyl peroxide, dicumyl peroxide, 2,2′-azobisisobutyronitrile, oxygen, nitrogen dioxide, and combinations or derivatives thereof.

Other photoinitiators or thermal free-radical initiators may also be utilised.

In some embodiments, the photoinitiator is present from about 0.001 wt. % to about 15 wt. % of the UV-curable polymer. In various embodiments, the photoinitiator may be present in an amount from about 0.002 to about 10 wt. %, from about 0.01 to about 5 wt. %, or from about 0.1 to about 3 wt. % of the binder.

When the SiC source material is 3D printed, the 3D printing composition may comprise SiC powder and the binder. Depending on the 3D printing method used, the binder or a precursor thereof may be combined with the SiC powder prior to the 3D printing process or, alternatively, the binder can be added to the SiC powder during the printing process (e.g., a binder jet process). The SiC powder may be present in the 3D printing composition in an amount of about 70 wt. % or more, such as about 75 wt. % or more, such as about 80 wt. % or more, such as about 85 wt. % or more, such as about 90 wt. % or more, such as about 95 wt. % or more, such as about 98 wt. % or more, and about 99.9 wt. % or less, such as about 99 wt. % or less, such as about 95 wt. % or less, such as about 90 wt. % or less, such as about 85 wt. % or less, such as about 80 wt. % or less, such as about 75 wt. % or less. The binder may be present in the 3D printing composition in an amount of about 30 wt. % or less, such as about 25 wt. % or less, such as about 20 wt. % or less, such as about 15 wt. % or less, such as about 10 wt. % or less, such as about 5 wt. % or less, such as about 2 wt. % or less, and about 0.1 wt. % or more, such as about 1 wt. % or more, such as about 5 wt. % or more, such as about 10 wt. % or more, such as about 15 wt. % or more, such as about 20 wt. % or more, such as about 25 wt. % or more. In some embodiments, the binder is combined with the SiC powder in the form of a similarly sized powder. In other embodiments, the binder is added to the SiC powder in liquid form and then cured into a solid during the 3D printing process.

In some embodiments, the source material can include a 3D printed part comprising SiC particles that is configured to hold loose (i.e., non-bound) SiC powder. In such embodiments, SiC can sublimate from both the powder and the 3D printed part holding the powder. Such a embodiments may be advantageous for being able to better control gas flow and thermal gradients while also having a free source of SiC.

In some embodiments, the 3D printed source material may be formed in a shape with one or more channels running therethrough. Such channels can be useful for allowing gas flow through the source material and the ability to better control thermal gradients within the source material.

In some embodiments, a component of the grower is formed from a 3D printed part. For example, at least a portion of the crucible 114, seed holder 124, source material holder 130, inlet 220, foamed structure 350, or insulation material 118 can be 3D printed. When such components are 3D printed, the ceramic material can include SiC, another ceramic material, or graphite. For example, the ceramic material can comprise carbon mixed with one or more metals, such as one or more of Ti, Zr, Hf, V, Nb, Ta, Cr, Mo, or W. If the part is formed from a composition containing SiC, the binder can be selected so that the remaining carbon scaffold after decomposition of the binder either envelops the SiC particles or bonds directly to the SiC particle surfaces.

The 3D printing composition for grower components may comprise graphite, a ceramic powder, or precursor thereof, and a binder. The ceramic precursor can comprise, for example, a mixture of a metal and a carbon material (e.g., graphite) that react to form a ceramic (e.g., metal carbide) at high temperatures. The properties of the graphite, ceramic, or ceramic precursor particles are preferably similar to those described above for SiC particles. Additionally, the binder can be any of those described above with respect to 3D printed source materials. The graphite, ceramic, or ceramic precursor powder may be present in the 3D printing composition in an amount of about 70 wt. % or more, such as about 75 wt. % or more, such as about 80 wt. % or more, such as about 85 wt. % or more, such as about 90 wt. % or more, such as about 95 wt. % or more, such as about 98 wt. % or more, and about 99.9 wt. % or less, such as about 99 wt. % or less, such as about 95 wt. % or less, such as about 90 wt. % or less, such as about 85 wt. % or less, such as about 80 wt. % or less, such as about 75 wt. % or less. The binder may be present in the 3D printing composition in an amount of about 30 wt. % or less, such as about 25 wt. % or less, such as about 20 wt. % or less, such as about 15 wt. % or less, such as about 10 wt. % or less, such as about 5 wt. % or less, such as about 2 wt. % or less, and about 0.1 wt. % or more, such as about 1 wt. % or more, such as about 5 wt. % or more, such as about 10 wt. % or more, such as about 15 wt. % or more, such as about 20 wt. % or more, such as about 25 wt. % or more.

Whether the 3D printed part is used as the source material or another component within the sublimation system, the part can be 3D printed from a 3D printing composition as described above using known 3D printing techniques. Some examples of suitable 3D printing techniques are described below. However, it should be understood that the disclosure does not limit the 3D printing method used, and further 3D printing methods may also be suitable.

In some embodiments, the 3D printed part is produced through a powder bed 3D printing process. Powder bed fusion processes generally refer to processes where a powder is selectively sintered or melted and fused, layer-by-layer to produce a three-dimensional article. In one embodiment, the powder bed fusion process includes one or more lasers in a process known as laser sintering. During laser sintering, a laser is used to provide a pattern and heat to cause the binder particles to fuse or sinter together in a predetermined way. In addition to using one or more lasers as the heat source, powder bed fusion can also be achieved through the use of other forms of electromagnetic radiation, including, for example, infrared radiation, microwave energy, radiant heating lamps, and the like. The heat source can be coherent or incoherent. When using an incoherent heat source, a mask can be used in order to produce a three-dimensional article according to a particular pattern.

Three-dimensional articles formed through powder bed fusion include a plurality of overlying and adherent sintered or melted layers made from a 3D printing composition. For instance, the three-dimensional article can be made from more than about 8 layers, such as more than about 10 layers, such as more than about 15 layers, such as more than about 20 layers, such as more than about 25 layers, such as more than about 30 layers, such as more than about 40 layers, such as more than about 50 layers, and generally less than about 200,000 layers, such as less than about 150,000 layers. The number of layers can depend upon the particular application and the size of the final product.

In some embodiments, a powdered 3D printing composition is spread over a forming surface. A heat source, such as one or more laser beams, moves relative to the powder bed for producing a pattern in the particles. In one embodiment, the pattern is computer-controlled. In order to produce the pattern, the one or more lasers can move and scan over the forming surface, the forming surface can be moved relative to the lasers, or both the forming surface and the laser can be moved simultaneously. After one layer of powder has been sintered or melted together, another layer of powder is added to the forming surface and sintered or melted repeating the process. The process repeats as the one or more lasers melt and fuse each successive layer to the previous layer until a three-dimensional article is formed.

In some embodiments, the 3D printing composition of the present disclosure is used in a multi-jet fusion process. During multi-jet fusion, different components are combined with the powder during the printing process. For example, during a multi-jet fusion process, the powder is applied in patterns similar to the process described above. In addition to applying the powder, however, a fusing agent (e.g., one of the binders described above or a curing promoter for such a binder) can also be selectively applied to the particles that are to fuse together. In addition, optionally a detailing agent can be applied selectively where the fusing action of the particles needs to be reduced or amplified. For example, the detailing agent can be used to reduce fusing at the boundary to produce a part with sharp or smooth edges. During multi-jet fusion, the three components can be applied in sequence and repeatedly to build up layers and form a part or article.

During the three-dimensional printing process, various properties of the powder composition assist in producing a product having the desired characteristics. For example, the powder composition made up of the particles is preferably flowable. The powder composition should also be sinterable, meaning that the individual binder particles can bond together through thermal bonding or other suitable means. Consequently, formulating a 3D printing composition so as to have a larger operating window can facilitate particle-to-particle bonding and layer-to-layer bonding.

The powder composition, in one embodiment, can be incorporated into a printer cartridge that is readily adapted for incorporation into a three-dimensional printer system. The printer cartridge can include a dispensing container contained within a housing. The dispensing container can be for feeding the powder composition into the three-dimensional printer system.

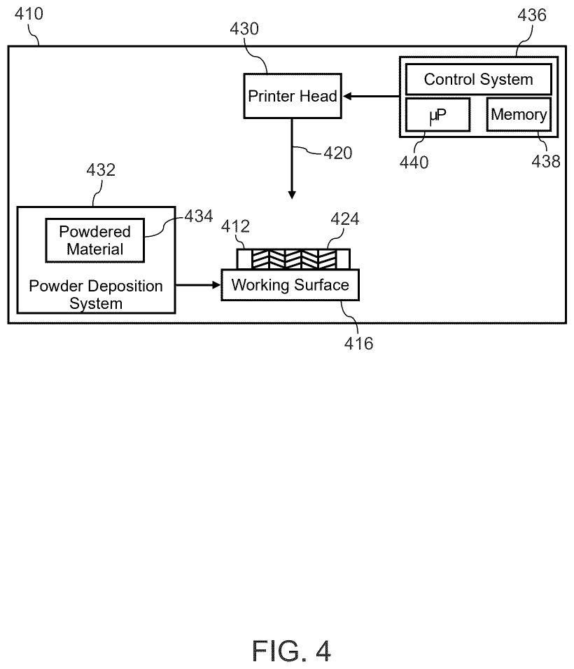

With reference to FIG. 4, an embodiment of a fusion bed printing system is presented. The printing system 410 comprises a functional platform 416 providing support for a layer of powder 412. Additionally, the system 410 incorporates a powder deposition system 432 responsible for depositing a powder composition 434, as disclosed herein, onto the working platform 416 to create the layer of powder 412.

The three-dimensional printing system 410 includes a printer head 430 emitting an energy source or 420 onto the powder 412 and the working surface 416. The printer head 430 includes, for example, one or more lasers or alternative energy sources. For example, the energy source may also be a binder as described herein or a curing agent for a binder precursor that is already contained in the powdered material 434.

Communication with a control system 436 is established for governing the printer head's operation. The control system 436, which may involve a distributed control system or a computer-based workstation, either fully or partially automated, encompasses memory circuitry 438 storing instructions for controlling the printer head 430. In some examples, the memory 438 holds CAD designs dictating the formation of a three-dimensional article on the working surface 416. Comprising one or more processing devices, such as a microprocessor 440, the control system 436 utilizes memory circuitry 438 consisting of tangible, non-transitory, machine-readable media collectively storing instructions executable by the processing device 440, facilitating the production of three-dimensional articles using the printer head 430.

As depicted in FIG. 2, during the printing process, the powder 412 can undergo heating to achieve a molten state to fuse the binder with the graphite or ceramic powder.

Alternatively, the binder can be selectively cured by a chemical agent to fuse the binder and the graphite or ceramic powder particles together. The individual particles undergo fusion, sintering, or bonding with the binder, and the three-dimensional article is formed in a layer-by-layer fashion, with each successive layer thermally or chemically bonding together.

As previously described, in some embodiments, the powder 412 is deposited onto the working platform 416. The layer of particles is then combined with a binder selectively applied in a specific pattern. Optionally, a detailing agent may also be applied to the particles following a prescribed pattern. Subsequently, energy is applied to facilitate the formation of a layer of the article.

Various other three-dimensional printing techniques, such as extrusion-based systems (e.g., fused deposition modeling) and electrophotography, may be employed. For instance, in a fused deposition modeling system, the 3D printing composition may function as a build material forming the three-dimensional structure and/or a support material removed from the structure post-formation.

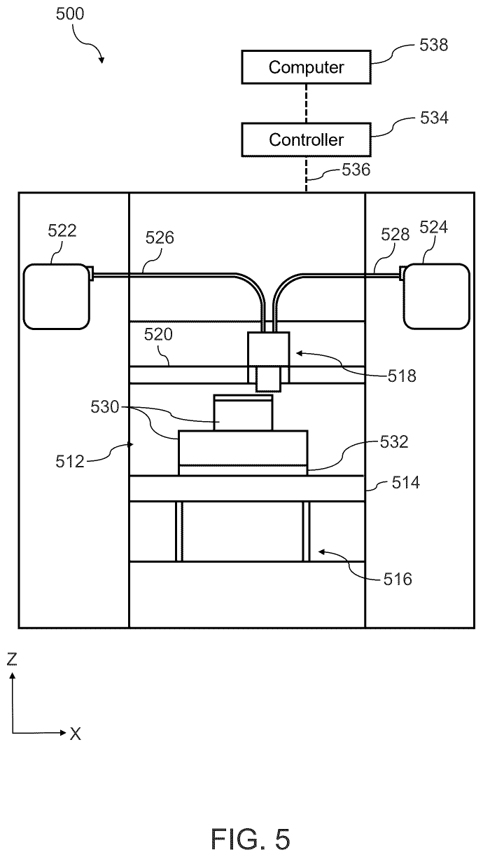

Referring to FIG. 5, an embodiment of an extrusion-based three-dimensional printer system 500 is illustrated. This system selectively forms a precursor object containing a three-dimensional build structure 530 and a corresponding support structure 532 within build chamber 512. The 3D printing composition described herein may be employed to form the build structure 530. Conventional materials may be employed for the support structure 532.

The system 500, including a controller 534, is equipped with a nozzle 518 for printing the build structure 530 and support structure 532 on a substrate 514. The nozzle 518 is attached to a head frame 520 allowing it to move side-to-side and front-to-back (i.e., in the X and Y directions). The nozzle 518 is connected to a build material reservoir 522 via a build material supply line 526 and a support material reservoir 524 via a support material supply line 528. The controller 534 communicates with the printing components via communication line 536 to monitor and operate the system components and may communicate with a computer 538 to transmit instructions for the selective formation of three-dimensional structures.

The build structure 530 is constructed layer-by-layer. In this regard, the build structure 530 is built on a build platform 514 which is moved vertically via support structures 516 (i.e., in the Z direction).

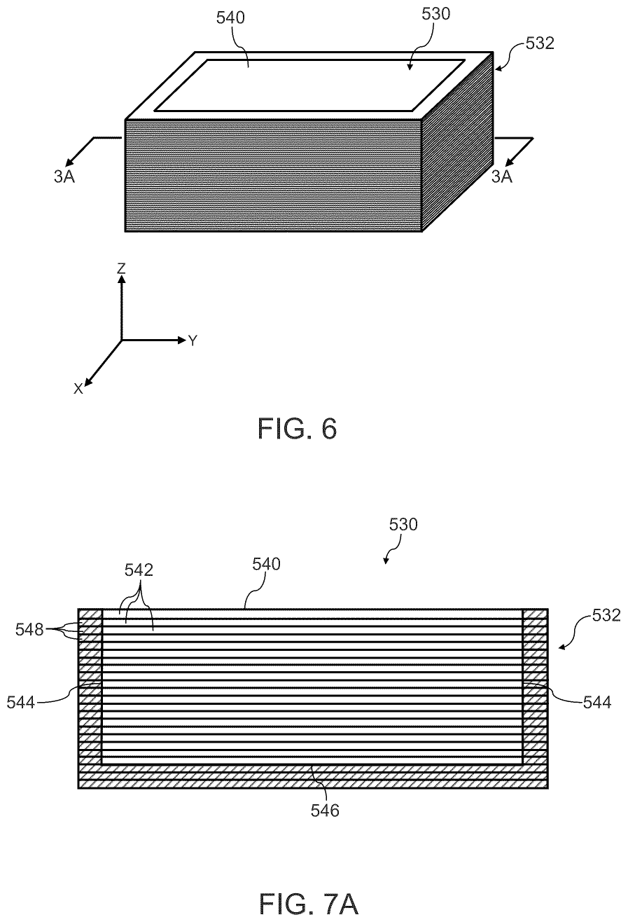

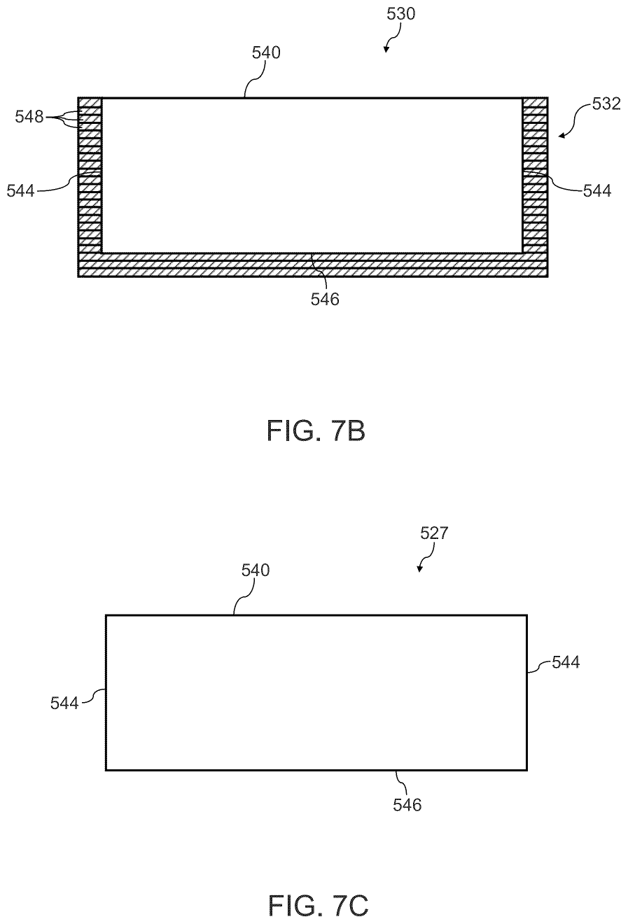

As shown in FIG. 6, the build structure 530 is printed onto the substrate 514 in successive layers of the build material, while the support structure 532 is concurrently printed in successive layers, coordinating with the build structure 530. The illustrated embodiment presents the build structure 530 as a simple block-shaped object, featuring a top surface 540, four lateral surfaces 544 (FIG. 7A), and a bottom surface 546 (FIG. 7A). While not obligatory, the support structure 532 in this embodiment is deposited to partially encapsulate the layers of the build structure 530. For instance, the support structure 532 may be printed to encapsulate the lateral surfaces and the bottom surface of the build structure 530. It should be noted that the system 510 may print three-dimensional objects with various geometries in alternative embodiments. In such cases, the system 510 may also print corresponding support structures, optionally partially encapsulating the three-dimensional objects.

FIGS. 7A-7C provide insight into the process of printing the three-dimensional build structure 524 and support structure 532 as described above. As depicted in FIG. 7A, each layer of the build structure 530 is printed in a series of layers 542 to define the geometry of the build structure 530. In this particular embodiment, each layer of the support structure 532 is printed in a series of layers 548, coordinating with the printing of layers 542 of the three-dimensional build structure 530. The printed layers 548 of the support structure 532 encapsulate the lateral surfaces 544 and the bottom surface 546 of the build structure 530, while the top surface 540 remains unencapsulated by the layers 548 of the support structure 532. Upon completion of the print operation, the support structure 532 can be removed from the build structure 530, resulting in the creation of a three-dimensional object 527. For instance, in embodiments where the support material is at least partially soluble in water or an aqueous alkaline solution, the resulting object may undergo immersion in a water and/or aqueous alkaline solution bath to dissolve the support structure 532.

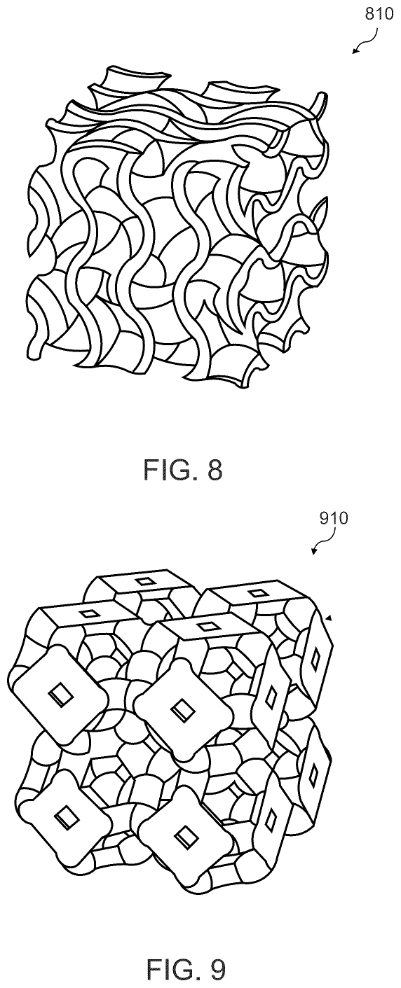

The use of 3D printing methods, including those described above, allows for the production of complex structures that could not be produced, or would be very difficult to produce by conventional methods. For example, FIGS. 8-16 and 18A-22B depict example complex structures that may be 3D printed according to example embodiments of the present disclosure.

One example embodiment of a 3D printed complex structure is shown in FIG. 8. The structure 810 is in the shape of a gyroid. The gyroid shape provides tortuous gas paths through the source material, which may influence thermal gradients and sublimation rates. The structure 810 also has a relatively high surface area which can provide high sublimation rates. If desired, holes or channels may be provided within the surfaces of the structure to improve the thermal performance of the source material (e.g., provide pathways for radiative heat to penetrate to the interior portions of the structure).

Another example embodiment of a 3D printed complex structure is shown in FIG. 9. The structure 910 is in the shape of a Kelvin structure containing numerous Kelvin unit-like cells. The structure 910 is an example of a structure which has a high surface area for high sublimation rates. Structure 910 also provides many pathways for radiative heat to pass through the structure for more a more uniform temperature profile throughout the source material.

Further, structure 910 provides many gas pathways for sublimated SiC to exit the source material structure. Such gas pathways can help prevent the recondensation of the sublimated SiC onto the surfaces of the source material structure.

Another example embodiment of a 3D printed complex structure is shown in FIG. 10. The structure 1010 is formed from repeating unit cells in the shape of body centered cubic plates. The structure 1010 has a relatively high surface area which can provide high sublimation rates. If desired, holes or channels may be provided within the surfaces of the structure to improve the thermal performance of the source material (e.g., provide pathways for radiative heat to penetrate to the interior portions of the structure).

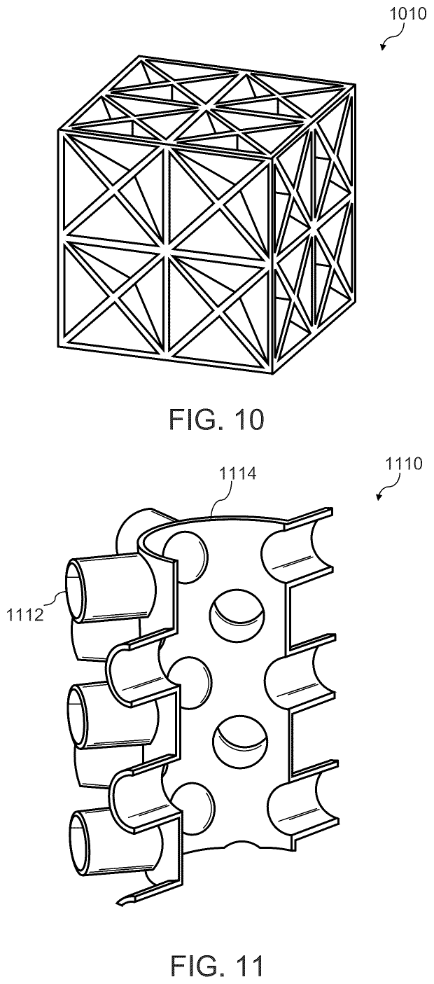

A cross section of another example embodiment of a 3D printed complex structure is shown in FIG. 11. The structure 1110 contains multiple tubular substructures 1112 projecting outward from a core tubular structure 1114. The structure 1110 also contains numerous channels, such as that within the core tubular structure 1114 and those within he tubular substructures 1112. The structure 1110 has a relatively high surface area which can provide high sublimation rates. Structure 1110 also provides many pathways for radiative heat to pass through the structure for more a more uniform temperature profile throughout the source material. Further, structure 1110 provides many gas pathways for sublimated SiC to exit the source material structure. Such gas pathways can help prevent the recondensation of the sublimated SiC onto the surfaces of the source material structure.

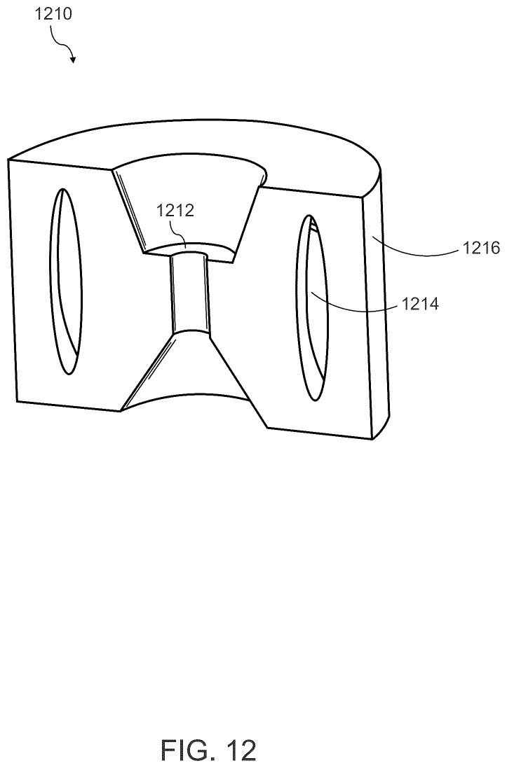

A cross section of another example embodiment of a 3D printed complex structure is shown in FIG. 12. The structure 1210 contains is generally cylindrical with modifications. For example, the structure contains a channel 1212 running from the top surface to the bottom surface of the cylinder. The structure 1210 also contains a void 1214. The structure 1210 is an example of a structure that may provide directionally controlled thermal gradients. For example, heat may flow more efficiently in the axial direction relative to the radial direction, as the outer wall 1216 may act as a barrier to the radiative heat, preventing it from efficiently flowing to inner portions of the structure.

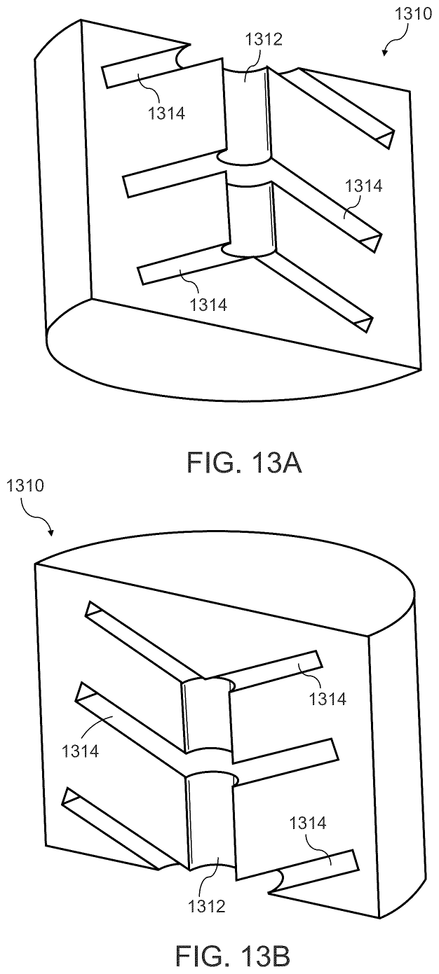

A cross section of another example embodiment of a 3D printed complex structure is shown in FIG. 13A. The structure 1310 is generally cylindrical with modifications. For example, the structure contains a hole 1312 in the bottom surface of the cylinder. The structure 1310 also contains slots 1314. The slots 1314 can help transfer vapor from the surrounding solid regions and into the hole 1312 before exiting the source and passing to the seed material/growing crystal. In another embodiment, the structure 1310 may be flipped such that the hole 1312 faces downward within the reaction crucible, as shown in FIG. 13B.

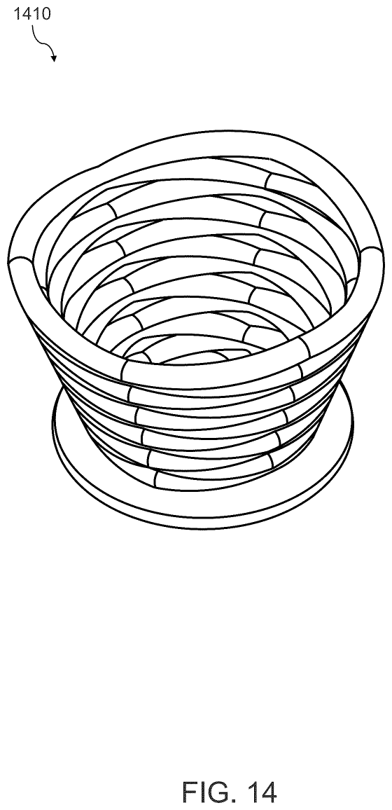

Another example embodiment of a 3D printed complex structure is shown in FIG. 14. The structure 1410 contains multiple curved rods. The structure 1410 has a high surface area for high sublimation rates and also provides many thermal and vapor flowpaths.

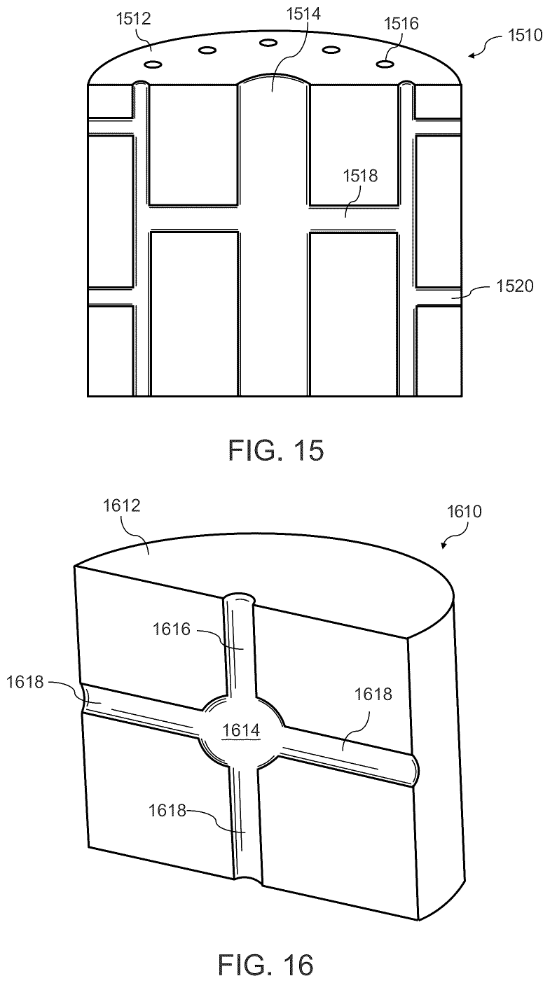

A cross-section of another example embodiment of a 3D printed complex structure is shown in FIG. 15. The composite structure 1510 contains a cylindrical base 1512 modified with a network of channels. For example, the structure 1510 contains a central channel 1514 running from the top surface to the bottom surface of the structure 1510. The structure 1510 also contains peripheral channels 1516 surrounding the central channel 1514 running from the top surface to the bottom surface of the structure 1510. The peripheral channels 1516 are connected to the central channel 1514 and the outer surface of the structure 1510 by horizontal channels 1518. It should be understood that, in other embodiments, peripheral channels 1516 may be connected only to the outer surface of the structure 1510 by horizontal channels 1518 and not to the central channel 1514. Similarly, in some embodiments, the structure may contain peripheral channels 1516 connected to the outer surface of the structure 1510 by horizontal channels 1518 and not contain a central channel, such as 1514, at all. Alternatively, peripheral channels 1516 may be connected only to the central channel 1514 by horizontal channels 1518 and not to the outer surface of the structure 1510. The various channels may be strategically placed to draw silicon carbide vapor from the surrounding solid portions of the source material and direct it as desired.

A cross-section of another example embodiment of a 3D printed complex structure is shown in FIG. 16. The composite structure 1610 contains a cylindrical base 1612 modified with a network of channels. For example, the structure 1610 contains an interior cavity 1614 connected to the outside surfaces of the structure 1610 by vertical channels 1616 and horizontal channels 1618. The various channels may be strategically placed to draw silicon carbide vapor from the surrounding solid portions of the source material and direct it as desired.

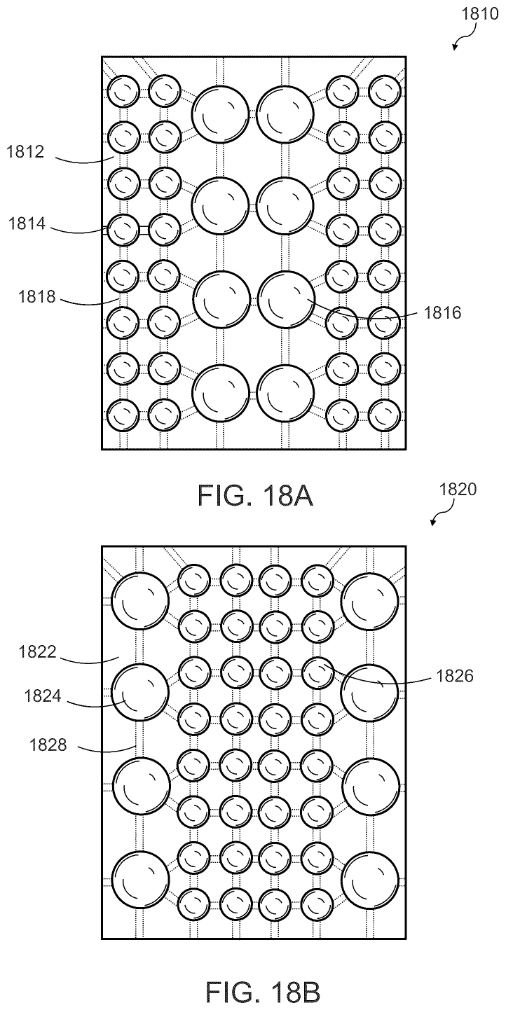

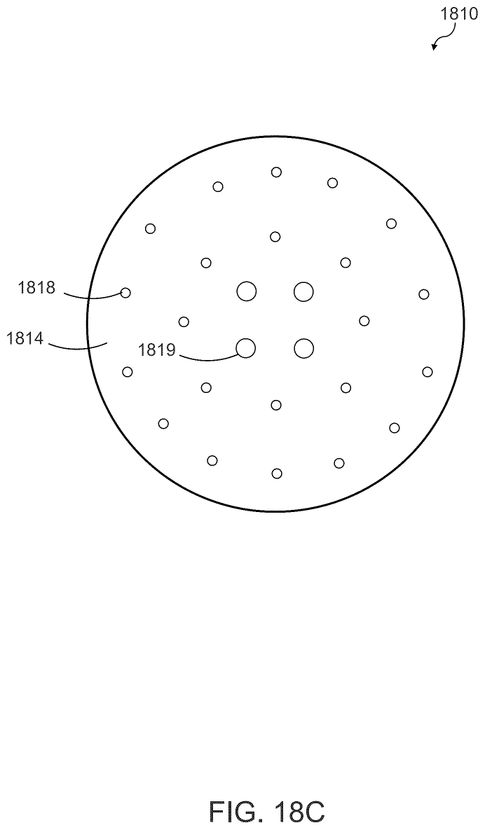

A cross-section of another example embodiment of a 3D printed complex structure is shown in FIG. 18A. The complex structure (e.g., source material) 1810 includes a cylindrical base 1812 with numerous voids, including small voids 1814 and large voids 1816, formed therein. The large voids 1816 are in the center of the cylinder and the small voids 1814 radially surround the large voids 1816. FIG. 18B shows another embodiment of a complex structure (e.g., source material) 1820 that is similar to 1810 (FIG. 18A) except that the smaller voids 1826 are in the central portion and the larger voids 1824 are in the peripheral portion of the cylindrical base 1822. As such, the embodiment shown in FIG. 18B may have contrasting sublimation characteristics compared to the embodiment shown in FIG. 18A.

In some embodiments, any voids formed within the source structure may be interconnected. For example, FIG. 18A contains interconnecting channels 1818 and FIG. 18B contains interconnecting channels 1828. As shown, the channels may connect the voids vertically, horizontally, or on any other angle (e.g., between 10 and 80 degrees with respect to the vertical axis). As shown in FIGS. 18A and 18B, the voids may also be vented through the outer wall of the cylindrical base through channels extending radially outward from the voids.

The voids may also be vented out the top and/or bottom of the source structure through channels that extend axially from the voids to the exterior of the structure through the top or bottom surfaces. The voids may also be vented through angled channels (i.e., non-perpendicular and non-parallel to the vertical axis), as shown in in the top sections of FIGS. 18A and 18B. In general, the voids may be interconnected and vented to various locations as desired based on the vapor flow paths desired within the crucible. For example, in some embodiments, the voids may be vented out the sides but not the top. In some embodiments, the voids may be vented out the top but not the sides. In some embodiments, there may be no channels venting the voids to the exterior at all. In some embodiments, various voids may be vented to the exterior but not interconnected with each other.

A top view of the complex structure 1810 (shown in FIG. 18A) is shown in FIG. 18C. As shown, the channels 1818 vent the voids to the top surface of the structure. The channels may be sized based on the desired gas flow rates and thermal gradients. For example, some channels may be larger in diameter than others. As shown in FIG. 18C, for instance, channels 1819 are located in the center of the source material structure and are larger than channels 1818. In some embodiments, however, the diameters of the channels may all be the same. In other embodiments, channels on the periphery of the source structure may be larger than those in the center.

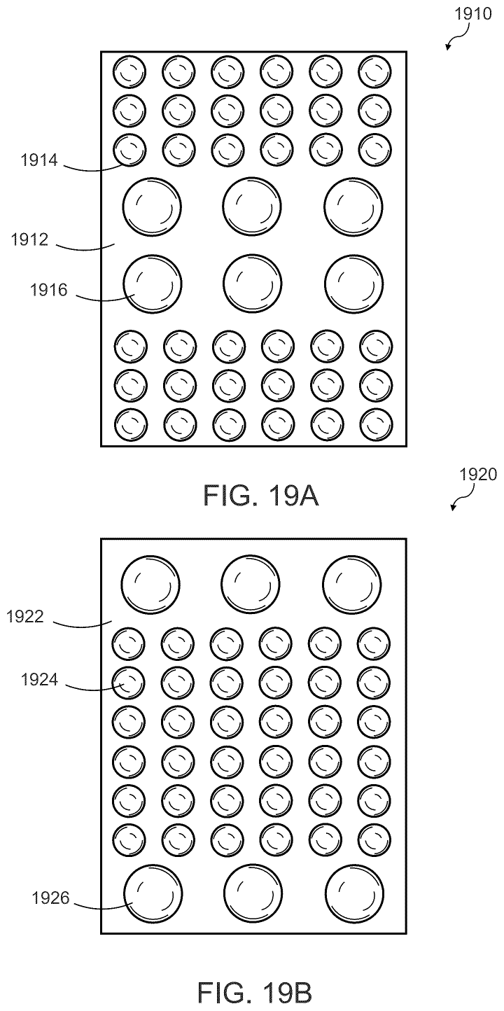

A cross-section of another example embodiment of a 3D printed complex structure is shown in FIG. 197A. The complex structure (e.g., source material) 1910 includes a cylindrical base 1912 with numerous voids, including small voids 1914 and large voids 1916, formed therein. The large voids 1916 are in the center of the cylinder and the small voids 1914 are formed above and below the large voids 1916. Such a configuration may be used when there is a temperature gradient vertically within the crucible or if it is desired to have various sublimation rates at different times during the growth process. FIG. 19B shows another embodiment of a source structure 1920 that is similar to 1910 (FIG. 19A) except that the smaller voids 1924 are in the central portion and the larger voids 1926 are in the upper and lower portions of the cylindrical base 1922. As such, the embodiment shown in FIG. 19B may have contrasting sublimation characteristics compared to the embodiment shown in FIG. 19A.

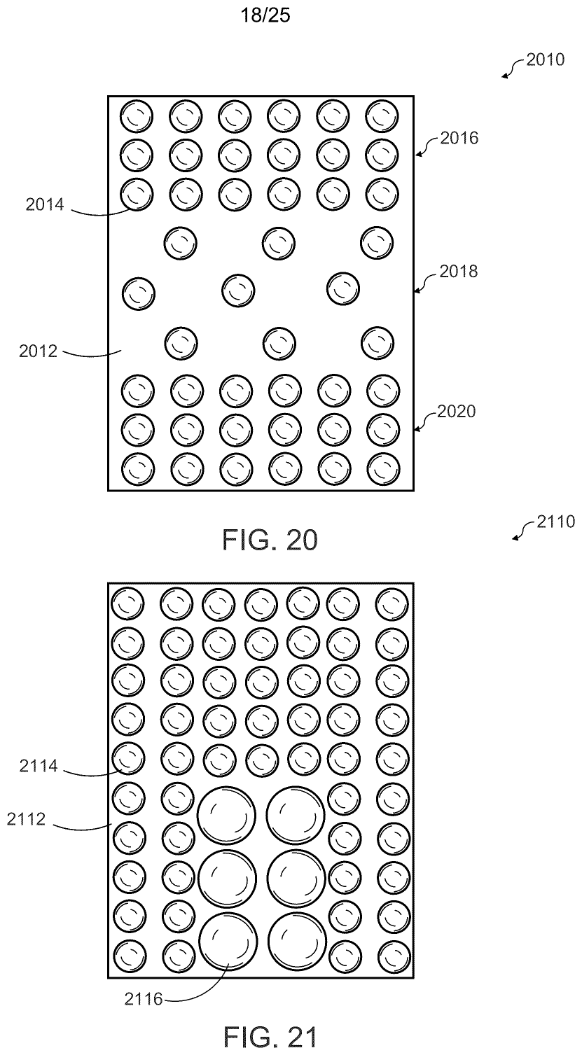

FIG. 20 shows a cross-section of another example embodiment of a complex structure which may be 3D printed. The complex structure (e.g., source material) 2010 includes a cylindrical base 2012 with numerous voids 2014 formed therein. In this embodiment, rather than changing the size of the voids to control the sublimation properties, the concentration of the voids is varied along the height of the cylindrical base 2012. For example, the concentration of voids is relatively high at the top portion 2016 and the bottom portion 2020 and relatively low in the middle portion 2018.

FIG. 21 shows a cross-section of another example embodiment of a complex structure which may be 3D printed. The complex structure (e.g., source material) 2110 includes a cylindrical base 2112 with numerous voids, including small voids 2114 and large voids 2116, formed therein. The large voids 2116 are in the bottom portion of the center of the cylinder and the small voids 2114 surround the large voids 2116 on all sides except the bottom. Such an embodiment may be used to control the sublimation properties over time. For example, if sublimation is occurring relatively equally across all exposed areas of the surface of the cylinder (the bottom is not exposed as it is against the bottom surface of the crucible), then the outer portions of the source material may sublimate at a first rate during a first phase of crystal growth and then change to a second rate over time as the outer portions sublimate and expose the inner portion having a different void configuration. Alternatively, in other embodiments, the smaller voids may surround the larger voids on the bottom portion too.

It should be understood that in any of the embodiments shown in FIGS. 18A-21, the voids may be interconnected with each other through the use of holes or channels. Further, the embodiments are shown as examples of how sublimation properties and therefore the properties of the growing crystal can be controlled through the shape of the source material. However, other configurations may be designed based on the desired sublimation characteristics.

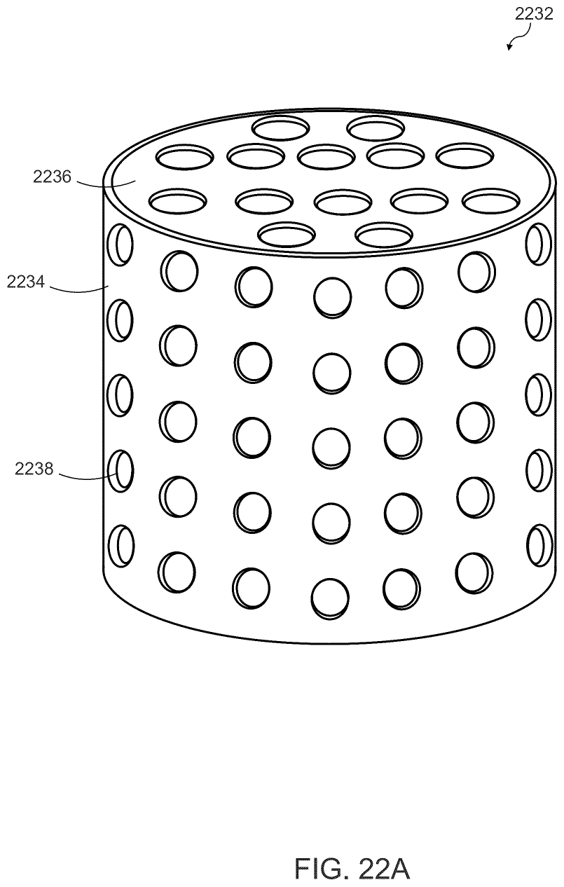

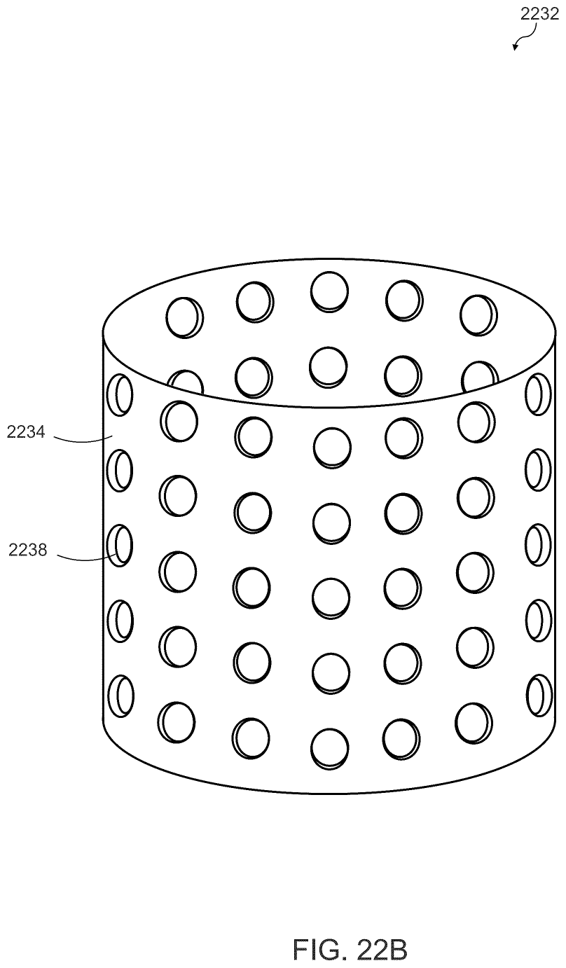

In any of the embodiments described herein, the source material may be contained within a source retention mechanism, which can filter or divert the flow of vapor as desired within the crucible. Example embodiments of source retention mechanisms are shown in FIGS. 22A and 22B. in FIG. 22A, the source retention mechanism 2232 contains cylindrical side walls 2234, a cap 2236, and channels 2238 formed in the side walls 2234 and the cap 2236. As shown in FIG. 22A, the channels may all have the same or a similar diameter. In some embodiments, the diameters of the channels may be different and designed based on desired vapor flow paths and flowrates. For example, in some embodiments, the cap may have larger channels, or even one large central channel, relative to smaller or no peripheral channels.

The retention mechanism can be used to contain a source material, particularly when it is formed from multiple separate shaped solids (e.g., spheres) or if it contains powder. The channels 2238 allow sublimated vapor to escape into the main chamber of the reaction crucible where they can reach the seed material or growing crystal. The channels may be designed/located to control the vapor flow within the crucible. For example, they can direct the vapor to specific parts of the seed material or growing crystal. In some embodiments, the channels in the side walls 2234 may be omitted so that sublimated vapor can only exit through the channels in the cap 2236. In some embodiments, the cap 2236 may be omitted, as shown in FIG. 22B. In some embodiments, rather than, or in addition to, channels 2238, the source walls and/or cap of the retention mechanism may be made from a highly porous material that the sublimated vapor can escape through.

In some embodiments, it may be desired to restrict vapor flow from either the sides or the top. As such, the sides or top of the retention mechanism may be formed from a material with no or relatively low porosity. The retention mechanism may be formed from graphite, silicon carbide, or any other suitable material. When the retention mechanism is formed from silicon carbide, it may act as an additional source structure. The retention mechanism may be sized to fit within the inner walls of the crucible. The retention mechanism may contact the sidewalls of the crucible or may be spaced apart from them, leaving paths for vapor flow radially outward from the retention mechanism.

The source retention mechanism may be 3D printed as described herein. It may be formed from a composition containing silicon carbide particles and function as a secondary source material or it may be formed a composition containing graphite particles or other ceramic particles.

The structures illustrated in FIGS. 4-16 and 18A-22B contain holes, grooves, and angles that cannot be, or would be difficult to be, lathed/machined etc. Such structures may be used to enhance temperature uniformity, desired gas flow etc. Such illustrations are provided as examples of the types of structures that can be 3D printed, but it should be understood that many other types of structures can be produced by the methods described herein. Additionally, the structures illustrated may be incorporated into larger structures forming the source material or grower parts.

When 3D printing is used to form a source material, the resulting 3D printed structure may have properties which enhance the sublimation process. For example, the 3D printed structure may have a material density (i.e., skeletal density) from about 1.0 g/cm³ to about 3.21 g/cm³, such as from about 1.4 g/cm³ to about 3.2 g/cm³, such as from about 2.0 g/cm³ to about 3.1 g/cm³, such as from about 2.5 g/cm³ to about 3.0 g/cm³. The apparent density of the source material structure may be from about 1.0 g/cm³ to about 3.21 g/cm³. The 3D printed structure may have an total porosity of about 5% or greater, such as about 10% or greater, such as about 20% or greater, such as about 30% or greater, such as about 40% or greater, such as about 50% or greater, such as about 60% or greater, such as about 70% or greater, and about 90% or less, such as about 80% or less, such as about 70% or less, such as about 60% or less, such as about 50% or less, such as about 40% or less. The 3D printed structure may have a ratio of open porosity to total porosity of about 0.5 or more, such as about 0.6 or more, such as about 0.7 or more, such as about 0.8 or more, such as about 0.9 or more. The combination of grain size, total porosity, open porosity, and density may be selectively controlled such that the solid source material exhibits high sublimation activation.

3D printed source materials, including source retention mechanisms such as those shown in FIGS. 22A and 22B, may also have portions with varying properties. For example, a 3D printed source material may contain one portion with a first porosity and another portion with a second porosity different from the first porosity. For example, the second porosity may differ by about 1% or more, such as 2% or more, such as 3% or more, such as 5% or more, such as 7% or more, such as 10% or more, such as 15% or more, such as 20% or more, such as 25% or more such as 30% or more, such as 40% or more, such as 50% or more from the first porosity. Such porosities may refer to total porosity or percentage of open porosity. Other properties, such as density and grain size may similarly vary in different portions of the 3D printed source material.

Further, the complexity of the 3D printed material may provide it with a relatively high surface area. For example, the ratio of the surface area of the 3D printed structure to the volume of the 3D printed structure may be greater than 2 cm⁻¹, such as about 2.1 cm⁻¹ or greater, such as about 2.5 cm⁻¹ or greater, such as about 3.0 cm⁻¹ or greater, such as about 3.5 cm⁻¹ or greater, such as about 4.0 cm⁻¹ or greater, such as about 4.5 cm⁻¹ or greater, such as about 5 cm⁻¹ or greater, even when, for example, the 3D printed structure has a length of at least 20 mm in a first direction and a length of at least 10 mm in a direction orthogonal to the first direction, or even when the volume of the shaped solid is 30 cm³ or more. Similarly, the 3D printed structure may have a relatively small volume relative to the space it takes up in the reaction crucible. For example, a ratio of the volume of the 3D printed structure to the volume of the smallest right cylinder that would fully contain the 3D printed structure may be less than 1, such as about 0.9 or less, such as about 0.8 or less, such as about 0.7 or less, such as about 0.6 or less, such as about 0.5 or less, such as about 0.4 or less, such as about 0.3 or less, and about 0.2 or more, such as about 0.5 or more. The total volume of the source material may be determined based on the density of the source material and the desired total volume of the crystal that will be grown.

Following 3D printing using any suitable method, including those described above, the resulting green component can undergo sintering, for example, by heating to a temperature of about 1500° C. or more.

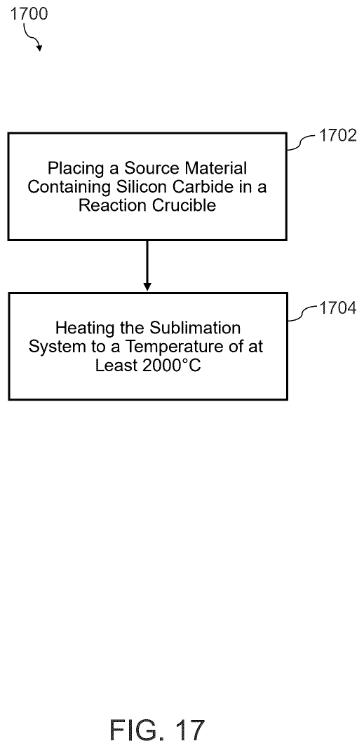

FIG. 17 depicts a flow chart diagram of an example method 1700 according to example embodiments of the present disclosure. FIG. 17 depicts example method steps for purposes of illustration and discussion. Those of ordinary skill in the art, using the disclosures provided herein, will understand that the methods described in the present disclosure may be adapted, modified, include steps not illustrated, omitted, and/or rearranged without deviating from the scope of the present disclosure.

In general method 1700 is a method for growing a single-crystal of silicon carbide (SiC crystal) using a physical vapor transport (PVT) process in a sublimation system. At (602), method 1700 may include placing a source material containing silicon carbide in a reaction crucible. The source material may comprise a 3D printed source material, loose (i.e., non-bound) SiC powder, or loose powder contained in a 3D printed source material structure. However, at least one component, which can be part of the source material or another grower component, or the sublimation system comprises a 3D printed part comprising graphite or a ceramic material, and a binder, as described above.

At (604), method 600 may comprise heating the sublimation system to at least a sublimation temperature of the silicon carbide source material structure, such as at least 2000° C. For example, a typical SiC sublimation process is described as follows. However, those familiar with the growth of crystals, particularly in difficult material systems such as silicon carbide, will recognize that the details of the given technique can vary depending on relevant circumstances.

Typically, growth pressure during an applied PVT process will range from about 0.1 to 400 Torr, and more typically between about 0.1 and about 100 Torr. The process temperature will range from about 2000° C. to about 3000° C. and in some embodiments, from about 2000° C. to about 2500° C. These conditions may vary due to differences in the sublimation system being used and variations in the seeded sublimation growth process being run. The thermal gradient between the growing crystal and the source material is typically controlled in a range of about 50 to 150° C./cm. A sublimating SiC species flux during the process period may be controlled by a ramped increase in the growth temperature in the range of about 0.3 to about 10° C./hr.

The sublimation process may include the steps of first evacuating the environment around the reaction crucible to remove ambient air, gaseous impurities and extraneous solid particulates. Then, the reaction crucible may be placed under pressure using one or more inert gas(es). Then, the sublimation system may heat the reaction crucible environment to a temperature enabling SiC crystal growth via PVT. Once this temperature is reached, the pressure within the sublimation system may be reduced to a point sufficient to initiate SiC crystal growth. In some embodiments, one or more carrier gasses (e.g., H₂, CH₄, Cl) may be used to increase growth rate or control the ratio of Si to C in the vapor.

In certain embodiments of the present disclosure, one or more type of dopant atoms may be intentionally introduced into sublimation system during or before the seeded sublimation process. For example, one or more dopant gases may be introduced into the seeded sublimation environment and thereby incorporated into the growing SiC crystalline boule. Dopants may be selected for their acceptor or donor capabilities in accordance with the conductivity properties desired for the resulting SiC boule. For certain semiconductor devices, donor dopants produce n-type conductivity and acceptor dopants produce p-type conductivity. Some commonly incorporated n-type dopants include N, P, As, Sb, and/or Ti. Some commonly incorporated p-type dopants include B, Al, Ga, Be, Er, and/or Sc.

With reference again to FIG. 1, in a typical sublimation growth process according to some embodiments, an electrical current having a defined frequency to which the material (e.g., carbon) forming reaction crucible 114 will respond is passed through induction coils 116 to heat reaction crucible 114. The amount and placement of insulation material 118 are selected to create a thermal gradient between a source material 120 and a seed material 122. Reaction crucible 114 is heated with source material 120 to a sublimation temperature above about 2000° C. In this manner, a thermal gradient is established such that the temperature of seed material 122 and the SiC crystalline boule 126 growing on the seed material 122 remains slightly below the temperature of source material 120. In this manner, certain vaporized species generated from the sublimating SiC source (e.g., Si, Si₂C and/or SiC₂) are thermodynamically transported first to seed material 122 and thereafter to the growing SiC crystalline boule 126 (or “the SiC crystal”). The SiC crystal may have a 4H crystal structure, 6H crystal structure, 3C crystal structure, or other crystal structure, depending on the seed material used.

Once the SiC crystal 126 has reached a desired size, the crystal growth process may be terminated by reducing the temperature of sublimation system 112 below about 1900° C. and/or raising the pressure of the environment surrounding reaction crucible 114 above about 400 Torr.

Wafers cut from such SiC crystals may be subsequently used in the fabrication of various substrates. For example, using known techniques, high quality semiconductor wafers may be fabricated that include homo-epitaxial layers, such as SiC, as well as hetero-epitaxial layers, such as Group III-nitrides, on at least one surface thereof. The Group III-nitride layer may be, for example, GaN, AlGaN, AIN, AlInGaN, InN, and/or AlInN.

The SiC substrate will include at least one and possibly two primary (and opposing) surfaces. A plurality of active and/or passive devices may be fabricated on the SiC substrate.

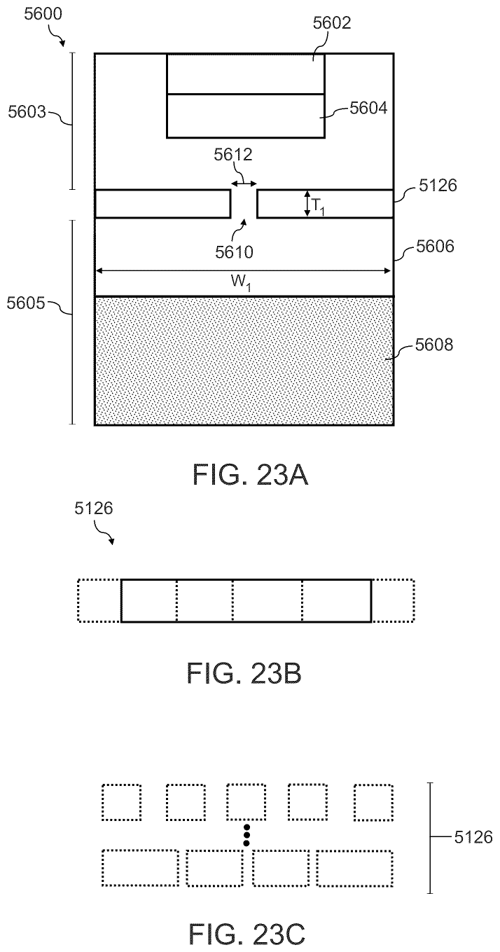

FIGS. 23A-30 depict example crystal growth systems that include a baffle according to example embodiments of the present disclosure. Any of the components of the crystal growth systems of FIGS. 23A-30 may be 3D printed structures according to example embodiments of the present disclosure.

FIG. 23A depicts a simplified view of a crystal growth system 5600 according to example aspects of the present disclosure. The crystal growth system 5600 includes the seed holder 5602 configured to hold the seed crystal 5604. The seed crystal 5604 may provide a growth surface for growth of the silicon carbide crystalline material in a crystal growth process. The crystal growth system 5600 includes the crucible 5606 defining a crystal growth chamber.

The crystal growth system 5600 includes the source material 5608. The crystal growth system 5600 includes a baffle 5126 within the crystal growth chamber that is spaced apart from the source material 5608. In some embodiments, the baffle 5126 may extend between the inner walls of the crucible 5606, such that the crucible 5606 is bisected or divided into an upper portion 5603 and a lower portion 5605 by the baffle 5126. The upper portion 5603 and the lower portion 5605 may have the same or different volumes. In some examples, the baffle 5126 may be coupled to a side wall of the crucible 5606. In some examples, the baffle 5126 may not fully extend between the inner walls of the crucible 5606.

The baffle 5126 has a long dimension (e.g., width) W1 and a thickness T1. The thickness T1 is in a general direction of vapor transport through the baffle 5126. In some embodiments, the long dimension W1 is in a direction that is non-perpendicular to the growth surface of the seed crystal 5604.

FIG. 23B depicts a simplified view of baffle 5126 according to some aspects of the present disclosure. As shown in FIG. 23B, baffle 5126 may include apertures, and may extend to the side walls of the crucible, or may not extend to the sidewalls of the crucible.

FIG. 23C depicts a simplified view of baffle 5126 according to some aspects of the present disclosure. As shown in FIG. 23C, baffle 5126 may include multiple baffle structures, which may be spaced apart from one another or may be in contact with one another.

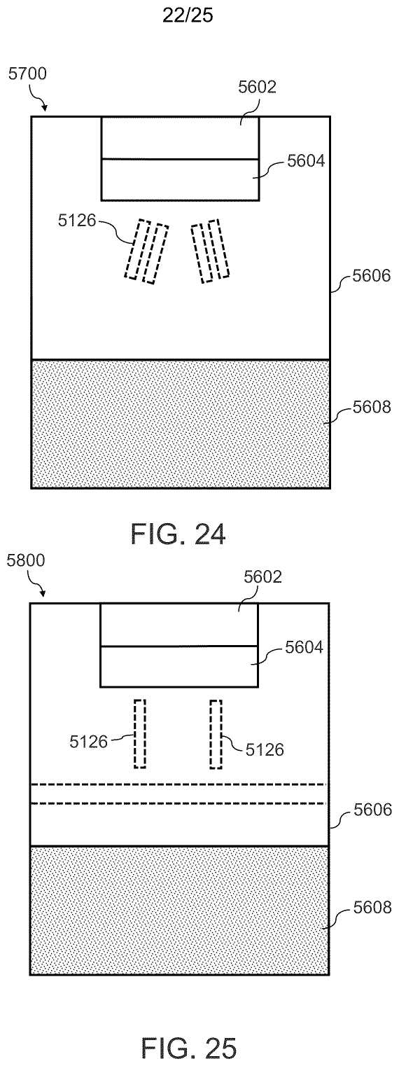

FIGS. 24, 25, 26, 27, 28, 29 and 30 depict simplified views of a baffle 5126 according to some aspects of the present disclosure in the context of crystal growth systems 5700, 5800, 5900, 6000, 6050, 6100, and 6200. As shown in FIG. 24, in some embodiments of the present disclosure, baffle 5126 may include one or more baffle plates, in any orientation relative to the seed holder 5602 or the source material 5608. As shown in FIG. 25, in some embodiments of the present disclosure, the baffle 5126 may include two or more baffle structures, whether of the same type or of differing types, and such baffle structures may be of differing orientations relative to each other.

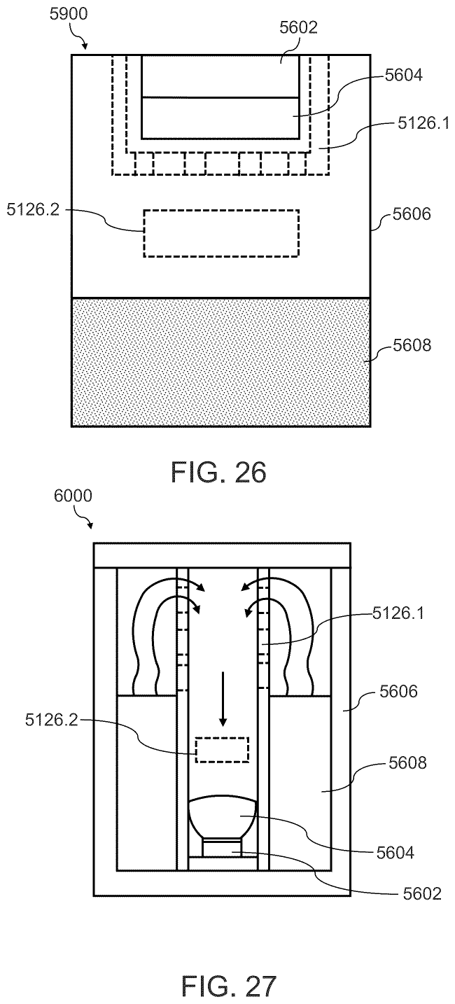

FIG. 26 depicts an example crystal growth system 5900 according to example embodiments of the present disclosure. In FIG. 26, the crystal growth system 5900 includes the baffle 5126.1, the seed holder 5602, the seed crystal 5604, the crucible 5606, and the source material 5608. The baffle 5126.1 may or may not include any apertures. The baffle 5126.1 may be porous graphite and may have a porosity of greater than about 70%. The baffle 5126 may be positioned such that the baffle 5126.1 extends around at least three sides of the seed crystal 5604, with the longest dimension located below the seed crystal 5604. The baffle 5126.1 may be referred to as a shell structure as it provides a shell around the seed crystal 5604. The baffle 5126 may be graphite, such as porous graphite. The baffle 5126.1 may include one or more apertures 5610 that assist in the transport of source vapor from the source material 5608 to the seed crystal 5604. The system 5900 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

FIG. 27 depicts an example crystal growth system 6000 according to example embodiments of the present disclosure. In FIG. 27, the crystal growth system 6000 includes a baffle 5126.1, a seed holder 5602, a seed crystal 5604, a crucible 5606, and the source material 5608. The baffle 5126.1 may include a tubular baffle structure. The baffle 5126.1 may or may not include apertures. The seed crystal 5604 may be within the tubular baffle 5126.1. The baffle 5126.1 may be graphite, such as porous graphite. The baffle 5126.1 may be porous graphite and may have a porosity of greater than about 70%. The baffle 5126.1 may include one or more apertures 5610 that assist in the transport of source vapor from the source material 5608 to the seed crystal 5604. The system 6000 may further include one or more second baffles 5126.2. The one or more second baffles 126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference. The baffle 5126.1 and/or the baffle 5126.2 may serve to reduce graphite inclusions or other impurities resulting from gravitational forces pulling impurities toward the seed crystal 5604.

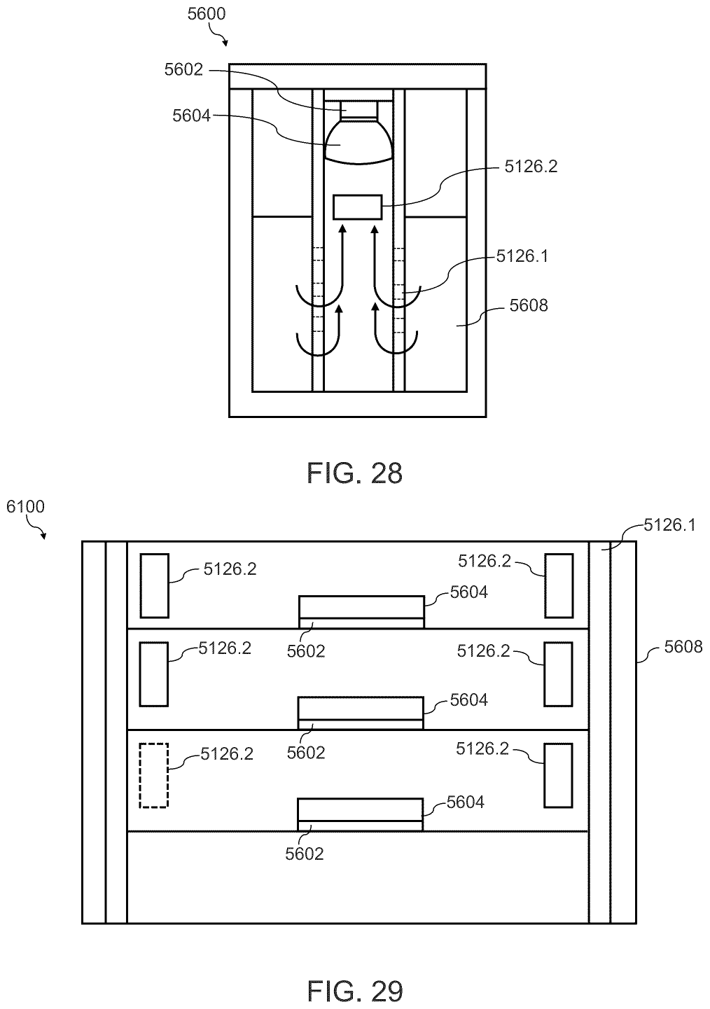

In FIG. 28, the crystal growth system 6050 includes the seed crystal 5604 at the top of the crucible 5606. Similar to FIG. 27, the baffle 5126.1 may include a tubular baffle structure.

The seed crystal 5604 may be within the tubular baffle 5126.1. The baffle 5126.1 may be graphite, such as porous graphite. The baffle 5126.1 may be porous graphite and may have a porosity of greater than about 70%. The baffle 5126.1 may include one or more apertures 5610 that assist in the transport of source vapor from the source material 5608 to the seed crystal 5604. The system 6000 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

FIG. 29 depicts an example crystal growth system 6100 that may be used to grow a plurality of silicon carbide boules according to example embodiments of the present disclosure. In FIG. 29, the crystal growth system 6100 includes a plurality of seed holders 5602 and seed crystals 5604 arranged in different crystal growth chambers. A baffle 5126.1 may separate the seed crystals 5604 from a source material 5608. The baffle 5126.1 may include one or more apertures to assist with vapor transport from the source material 5608 to the seed crystals 5604. The system 6100 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

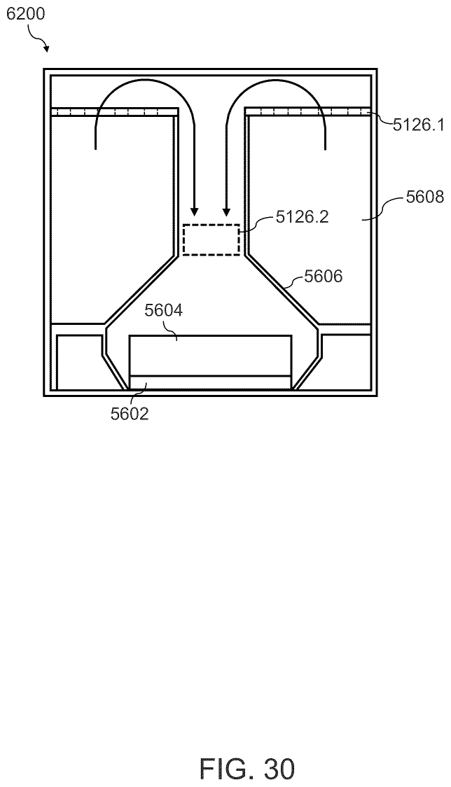

FIG. 30 depicts an example crystal growth system 6200 according to example embodiments of the present disclosure. In FIG. 30, the crystal growth system 6200 includes a seed holder 5602 and a seed crystal 5604 arranged within a crucible 5606. The crucible 5606 may have one or more angled sidewalls. The crystal growth system 6200 includes a source material 5608. The baffle 5126.1 may be on top of the source material 5608 and may separate the source material 5608 from the reaction chamber defined by the crucible 5606. As depicted in FIG. 23, the baffle 5126.1 may include one or more apertures to assist with vapor transport from the source material 5608 to the seed crystal 5604. The system 6100 may further include one or more second baffles 5126.2. The one or more second baffles 5126.2 may be arranged in the vapor transport path between the source material 5608 and the seed crystal 5604. The one or more second baffles 5126.2 may include any of the baffles disclosed in U.S. patent application Ser. No. 18/962,454 filed on Nov. 27, 2024, which is incorporated herein by reference.

In any of the simplified crystal growth systems with a baffle 5126.1, 5126.2 depicted in FIGS. 23A-30 or baffle 126 of FIGS. 1-3, the baffle may provide vapor transport of a silicon carbide source vapor through a first portion of the baffle at a first rate. In some embodiments, the silicon carbide vapor may be transported through a second portion of the baffle (e.g., including one or more apertures), at a second rate. The first rate may be different than the second rate. For example, the baffle may provide an avenue for source vapor to diffuse through the material of the baffle at a first rate, while source vapor is transported through an aperture unimpeded by the material of the baffle at a second rate.

In some embodiments, the baffle may be spaced apart from the seed holder and is not coupled to the seed holder. In some embodiments, the baffle may impede or otherwise alter heat transfer or thermal energy within the crystal growth chamber in a crystal growth process.

In some embodiments, the baffle may be, at least partially, made of graphite. In some embodiments, the baffle made at least partially of graphite may include a coating on at least a portion of the graphite. In some embodiments, the coating on the baffle made of graphite may be a pyrolytic coating. In some embodiments, the coating on the baffle made of graphite may be tantalum carbide. In some embodiments, the coating on the baffle may hinder particulate matter larger than the source vapor from reaching a seed crystal. The seed crystal may be a silicon carbide seed crystal. Example coatings that may be used are disclosed in U.S. Provisional Application Serial No. No. 63/700,682, filed on Sep. 28, 2024, U.S. Provisional Application Ser. No. 63/700,685, filed on Sep. 28, 2024 and U.S. Provisional Application Ser. No. 63/700,686, filed on Sep. 28, 2024, which are incorporated herein by reference. The baffle may have undergone various treatments (e.g., may be a treated graphite structure) to reduce carbon inclusions in the baffle. Example treated graphite structures are disclosed in U.S. Provision Application Ser. No. 63/700,630, filed on Sep. 28, 2024 which is incorporated herein by reference.

In some examples, the graphite is porous graphite. For instance, the baffle may have a porosity in a range of about 50% to about 97%, such as about 75% to about 97%, such as about 80% to about 97%. Other suitable materials may be used without deviating from the scope of the present disclosure. For instance, the baffle may comprise a carbide material, such as vanadium carbide, tantalum carbide, silicon carbide. The carbide material may form a bulk of the baffle.

In some examples, at least a portion of the baffle includes uncoated graphite or exposed graphite. For instance, at least a portion of a surface of the baffle facing the seed crystal may be exposed or uncoated graphite. This will allow that baffle to serve as a secondary source to improve crystal growth during a PVT crystal growth process.

The seed crystal may be a silicon carbide seed crystal. In some embodiments, the baffle may be spaced apart from a seed holder and is not coupled to the seed holder. In some embodiments, the baffle may be spaced apart from a source material and is not coupled to the source material. The source material may be a silicon carbide vapor source material. In some embodiments, the baffle may be coupled to a side wall of a crucible. In some embodiments, the baffle, or an individual baffle plate in embodiments including a plurality of baffle plates or baffle structures, may have a thickness that is in a range of about 0.5 mm to about 25 mm, such as 2 mm to about 12 mm, such as about 2 mm to about 8 mm.

In some embodiments, the baffle can include single or multiple elements that perform one of more of the following: effecting/providing temperature gradient in a desired manner relative to the crystal growth surface, effecting/providing vapor pressure/flux/flow for/to/from the source material (e.g., silicon carbon source material, secondary source material, or dopant source relative to the crystal growth surface, side surface of the seed crystal and/or areas within the reactor susceptible to parasitic growth; and filtering graphite or other inclusions from the crystal. In some embodiments, different elements or portions of the baffle can provide different features, such as one element for filtering, another element acting as a secondary source (e.g., a graphite element that provides a carbon source and provides temperature gradient and vapor pressure/flux effects); and an element with apertures, pores, voids, cavities, indentations and/or protrusions to effect temperature gradient and/or vapor flow/pressure effects. One or more of the baffles 126 can be coated with a high temperature carbide, such as TaC or the like) while others are not. Portions or the entire baffle can be coated or not with a single, multiple and/or patterned coating(s), for instance, to achieve desired sublimation if acting as a secondary source, or to reduce sublimation if not intended to serve as a secondary source. Individual baffles or baffle elements can serve duplicate or different functions.

Example aspects of the present disclosure are set forth below. Any of the below features or examples may be used in combination with any of the embodiments or features provided in the present disclosure.

In an aspect, the present disclosure provides an example silicon carbide crystal growth sublimation system including a crucible and a 3D printed source material within the crucible. The source material includes silicon carbide powder and a binder.

In some implementations of the example silicon carbide crystal growth sublimation system, the binder includes a UV curable polymer adhesive.

In some implementations of the example silicon carbide crystal growth sublimation system, the silicon carbide powder has a median particle size from about 1 μm to about 50 μm.

In some implementations of the example silicon carbide crystal growth sublimation system, the silicon carbide powder includes from about 70 wt. % to about 99.5 wt. % of the source material.

In some implementations of the example silicon carbide crystal growth sublimation system, the binder includes from about 0.5 wt. % to about 30 wt. % of the source material.

In some implementations of the example silicon carbide crystal growth sublimation system, the 3D printed source material has a shape including at least one channel configured to allow gas flow through the source material.

In some implementations of the example silicon carbide crystal growth sublimation system, the binder forms a non-graphitizable carbon at pyrolysis temperatures in a range of about 1600° C. to 3000° C.

In some implementations of the example silicon carbide crystal growth sublimation system, the binder has a char yield of about 50% or more at pyrolysis temperatures in a range of about 1600° C. to about 3000° C.

In an aspect, the present disclosure provides an example silicon carbide crystal growth sublimation system. The system includes a crucible, a seed holder, an insulation material at least partially surrounding the crucible, and a source material including silicon carbide contained within the crucible. At least a portion of the crucible, seed holder, or insulation material is 3D printed from a 3D printing composition including a ceramic material and a binder.

In some implementations of the example silicon carbide crystal growth sublimation system, the ceramic material includes silicon carbide.

In some implementations of the example silicon carbide crystal growth sublimation system, the ceramic material includes carbon mixed with metal.

In some implementations of the example silicon carbide crystal growth sublimation system, the metal includes one or more of Ti, Zr, Hf, V, Nb, Ta, Cr, Mo, or W.

In some implementations of the example silicon carbide crystal growth sublimation system, the binder includes a UV curable polymer adhesive.

In some implementations of the example silicon carbide crystal growth sublimation system, the ceramic material includes from about 70 wt. % to about 99.5 wt. % of the composition.

In some implementations of the example silicon carbide crystal growth sublimation system, the binder includes from about 0.5 wt. % to about 30 wt. % of the composition.

In some implementations of the example silicon carbide crystal growth sublimation system, a portion of the crucible is 3D printed.

In some implementations of the example silicon carbide crystal growth sublimation system, a portion of the insulating material is 3D printed.

In some implementations of the example silicon carbide crystal growth sublimation system, a portion of the seed holder is 3D printed.

In some implementations of the example silicon carbide crystal growth sublimation system, the binder forms a non-graphitizable carbon at pyrolysis temperatures in a range of about 1600° C. to 3000° C.

In some implementations of the example silicon carbide crystal growth sublimation system, the binder has a char yield of about 50% or more at pyrolysis temperatures in a range of about 1600° C. to about 3000° C.

In an aspect, the present disclosure provides an example method of growing a single-crystal of silicon carbide (SiC crystal) using a physical vapor transport (PVT) process in a sublimation system. The method includes placing a source material containing silicon carbide in a reaction crucible and heating the sublimation system to a temperature of at least 2000° C. At least one component of the sublimation system includes a 3D printed part made from a 3D printing composition including a ceramic material and a binder.

In some implementations of the example method, the source material includes the 3D printed part and the ceramic material includes silicon carbide.

In some implementations of the example method, the binder includes a UV curable polymer adhesive.

In some implementations of the example method, the silicon carbide includes a silicon carbide powder having a median particle size from about 1 μm to about 50 μm.

In some implementations of the example method, the silicon carbide includes from about 70 wt. % to about 99.5 wt. % of the composition.

In some implementations of the example method, the binder includes from about 0.5 wt. % to about 30 wt. % of the composition.

In some implementations of the example method, the source material has a shape including at least one channel.

In some implementations of the example method, the sublimation system further includes a seed holder and an insulation material at least partially surrounding the crucible, and wherein the crucible, seed holder, or insulation material includes the 3D printed part.

In some implementations of the example method, the ceramic material includes silicon carbide.

In some implementations of the example method, the ceramic material includes carbon mixed with metal.

In some implementations of the example method, the metal includes Ti, Zr, Hf, V, Nb, Ta, Cr, Mo, and/or W.

In some implementations of the example method, the binder includes a UV curable polymer adhesive.

In some implementations of the example method, the ceramic material includes from about 70 wt. % to about 99.5 wt. % of the composition.

In some implementations of the example method, the binder includes from about 0.5 wt. % to about 30 wt. % of the composition.

In some implementations, the example method includes forming the 3D printed part by selectively curing a composition in the desired shape of the part to form a green component.

In some implementations, the example method further includes sintering the green component.

In some implementations of the example method, the sublimation system is heated to a temperature from 2000° C. to about 3000° C.

In some implementations of the example method, the binder may form a non-graphitizable carbon at pyrolysis temperatures in a range of about 1600° C. to 3000° C.

In some implementations of the example method, the binder has a char yield of about 50% or more at pyrolysis temperatures in a range of about 1600° C. to about 3000° C.

While the present subject matter has been described in detail with respect to specific example embodiments thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

1-8. (canceled)

9. A silicon carbide crystal growth sublimation system comprising:
a crucible;
a seed holder;
an insulation material at least partially surrounding the crucible; and
a source material comprising silicon carbide contained within the crucible;
wherein at least a portion of the crucible, seed holder, or insulation material is 3D printed from a 3D printing composition comprising graphite and a binder.

10. (canceled)

11. The silicon carbide crystal growth sublimation system of claim 9, wherein the ceramic material further comprises a metal.

12. The silicon carbide crystal growth sublimation system of claim 11, wherein the metal comprises one or more of Ti, Zr, Hf, V, Nb, Ta, Cr, Mo, or W.

13. The silicon carbide crystal growth sublimation system of claim 9, wherein the binder comprises a UV curable polymer adhesive.

14. The silicon carbide crystal growth sublimation system of claim 9, wherein the graphite comprises from about 70 wt. % to about 99.5 wt. % of the composition.

15. The silicon carbide crystal growth sublimation system of claim 9, wherein the binder comprises from about 0.5 wt. % to about 30 wt. % of the composition.

16. The silicon carbide crystal growth sublimation system of claim 9, wherein a portion of the crucible is 3D printed.

17. The silicon carbide crystal growth sublimation system of claim 9, wherein a portion of the insulating material is 3D printed.

18. The silicon carbide crystal growth sublimation system of claim 9, wherein a portion of the seed holder is 3D printed.

19. The silicon carbide crystal growth sublimation system of claim 9, wherein the binder forms a non-graphitizable carbon at pyrolysis temperatures in a range of about 1600° C. to 3000° C.

20. The silicon carbide crystal growth sublimation system of claim 9, wherein the binder has a char yield of about 50% or more at pyrolysis temperatures in a range of about 1600° C. to about 3000° C.

21. A method of growing a single-crystal of silicon carbide (SiC crystal) using a physical vapor transport (PVT) process in the silicon carbide crystal growth sublimation system of claim 9, the method comprising heating the sublimation system to a temperature of at least 2000° C.

22. The method of claim 21, comprising forming the 3D printed part by selectively curing a composition in the desired shape of the part to form a green component.

23. The method of claim 22, further comprising sintering the green component.

24. The method of claim 21, wherein the sublimation system is heated to a temperature from 2000° C. to about 3000° C.

25. A silicon carbide crystal growth sublimation system comprising:
a crucible;
a seed holder;
an insulation material at least partially surrounding the crucible; and
a source material comprising silicon carbide contained within the crucible;
wherein at least a portion of the crucible, seed holder, or insulation material is 3D printed from a 3D printing composition comprising a ceramic precursor comprising a metal and a carbon material configured to react to form a metal carbide, and a binder.

26. The silicon carbide crystal growth sublimation system of claim 25, wherein the metal comprises one or more of Ti, Zr, Hf, V, Nb, Ta, Cr, Mo, or W.

27. The silicon carbide crystal growth sublimation system of claim 25, wherein the metal comprises Ta.

28. The silicon carbide crystal growth sublimation system of claim 25, wherein the carbon material comprises graphite.

29. The silicon carbide crystal growth sublimation system of claim 25, wherein the binder comprises a UV curable polymer adhesive.
